(19) United States
(12) Patent Application Publication
(10) Pub. No.: US 2007/0290282 A1
(43) Pub. Date: Dec. 20, 2007

(54) BONDED CHIP ASSEMBLY WITH A MICRO-MOVER FOR MICROELECTROMECHANICAL SYSTEMS

(75) Inventors: Nickolai Belov, Los Gatos, CA (US); Peter David Ascanio, Fremont, CA (US); Donald Edward Adams, Pleasanton, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 11/553,421

(22) Filed: Oct. 26, 2006

Related U.S. Application Data
(60) Provisional application No. 60/813,817, filed on Jun. 15, 2006.

(51) Int. Cl. H01L 43/00

(52) U.S. Cl. 257/421

(57) ABSTRACT

An embodiment of a micro-mover in accordance with the present invention can include a movable plate hermetically sealed between a top cap wafer and a bottom cap wafer. A magnet disposed on one or both of the cap wafers. The movable plate can include current paths disposed within a magnetic field generated by the magnet, and coaxially with a surface of the movable plate. When current is applied to the current paths, the movable plate is urged some distance within a gap between the movable plate and a stationary portion disposed co-planar with the movable plate.

### CLAIM OF PRIORITY

This application claims benefit to the following U.S. Provisional Application:

U.S. Provisional Patent Application No. 60/813,817 entitled BONDED CHIP ASSEMBLY WITH A MICRO-MOVER FOR MICROELECTROMECHANICAL SYSTEMS, by Nickolai Belov et al., filed Jun. 15, 2006, Attorney Docket No. NANO-01041US0.

### CROSS-REFERENCE TO RELATED PATENT APPLICATIONS

This application incorporates by reference all of the following co-pending applications and the following issued patents:

U.S. patent application Ser. No. 11/177,550, entitled “Media for Writing Highly Resolved Domains,” by Yevgeny Vasilievich Anoikin, filed Jul. 8, 2005, Attorney Docket No. NANO-01032US1;

U.S. patent application Ser. No. 11/177,639, entitled “Patterned Media for a High Density Data Storage Device,” by Zhaohui Fan et al., filed Jul. 8, 2005, Attorney Docket No. NANO-01033US0;

U.S. patent application Ser. No. 11/177,062, entitled “Method for Forming Patterned Media for a High Density Data Storage Device,” by Zhaohui Fan et al, filed by Jul. 8, 2005, Attorney Docket No. NANO-01033US1;

U.S. patent application Ser. No. 11/177,599, entitled “High Density Data Storage Devices with Read/Write Probes with Hollow or Reinforced Tips,” by Nickolai Belov, filed Jul. 8, 2005, Attorney Docket No. NANO-01034US0;

U.S. patent application Ser. No. 11/177,731, entitled “Methods for Forming High Density Data Storage Devices with Read/Write Probes with Hollow or Reinforced Tips,” by Nickolai Belov, filed Jul. 8, 2005, Attorney Docket No. NANO-01034US1;

U.S. patent application Ser. No. 11/177,642, entitled “High Density Data Storage Devices with Polarity-Dependent Memory Switching Media,” by Donald E. Adams, et al., filed Jul. 8, 2005, Attorney Docket No. NANO-01035US0;

U.S. patent application Ser. No. 11/178,060, entitled “Methods for Writing and Reading in a Polarity-Dependent Memory Switching Media,” by Donald E. Adams, et al., filed Jul. 8, 2005, Attorney Docket No. NANO-01035US1;

U.S. patent application Ser. No. 11/178,061, entitled “High Density Data Storage Devices with a Lubricant Layer Comprised of a Field of Polymer Chains,” by Yevgeny Vasilievich Anoikin, filed Jul. 8, 2005, Attorney Docket No. NANO-01036US0;

U.S. patent application Ser. No. 11/004,153, entitled “Methods for Writing and Reading Highly Resolved Domains for High Density Data Storage,” by Thomas F. Rust et al., filed Dec. 3, 2004, Attorney Docket No. NANO-01024US1;

U.S. patent application Ser. No. 11/003,953, entitled “Systems for Writing and Reading Highly Resolved Domains for High Density Data Storage,” by Thomas F. Rust et al., filed Dec. 3, 2004, Attorney Docket No. NANO-01024US2;

U.S. patent application Ser. No. 11/004,709, entitled “Methods for Erasing Bit Cells in a High Density Data Storage Device,” by Thomas F. Rust et al., filed Dec. 3, 2004, Attorney Docket No. NANO-01031US0;

U.S. patent application Ser. No. 11/003,541, entitled “High Density Data Storage Device Having Erasable Bit Cells,” by Thomas F. Rust et al, filed Dec. 3, 2004, Attorney Docket No. NANO-01031US1;

U.S. patent application Ser. No. 11/003,955, entitled “Methods for Erasing Bit Cells in a High Density Data Storage Device,” by Thomas F. Rust et al., filed Dec. 3, 2004, Attorney Docket No. NANO-01031US2;

U.S. patent application Ser. No. 10/684,760, entitled “Fault Tolerant Micro-Electro Mechanical Actuators,” by Thomas F. Rust, filed Oct. 14, 2003, Attorney Docket No. NANO-01015US1;

U.S. patent application Ser. No. 10/685,045, entitled “Phase Change Media for High Density Data Storage,” by Thomas F. Rust, filed Oct. 14, 2003, Attorney Docket No. NANO-01019US1;

U.S. patent application Ser. No. 09/465,592, entitled “Molecular Memory Medium and Molecular Memory Integrated Circuit,” by Joanne P. Culver, et al., filed Dec. 17, 1999, Attorney Docket No. NANO-01000US0;

U.S. Pat. No. 5,453,970, entitled “Molecular Memory Medium and Molecular Memory Disk Drive for Storing Information Using a Tunnelling Probe,” issued Sep. 26, 1995 to Thomas F. Rust, et al.;

U.S. Pat. No. 6,982,898, entitled “Molecular Memory Integrated Circuit Utilizing Non-Vibrating Cantilevers,” Attorney Docket No. NANO-01011US1, issued Jan. 3, 2006 to Thomas F. Rust, et al.,;

U.S. Pat. No. 6,985,377, entitled “Phase Change Media for High Density Data Storage,” Attorney Docket No. NANO-01019US1, issued Jan. 10, 2006 to Thomas F. Rust, et al.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

This invention relates to high density data storage using molecular memory integrated circuits.

### BACKGROUND

Micro-Electro-Mechanical Systems (MEMS) is the integration of mechanical elements, sensors, actuators, and electronics on a common silicon substrate. There are numerous possible applications for MEMS and Nanotechnology. MEMS enables synergistic advantages between previously unrelated fields such as biology and microelectronics. For example, in biotechnology, MEMS and Nanotechnology are employed to enable new discoveries in science and engineering such as the Polymerase Chain Reaction (PCR) microsystems for DNA amplification and identification, micro-machined Scanning Tunneling Microscopes (STMs), biochips for detection of hazardous chemical and biological agents, and Microsystems for high-throughput drug screening and selection.

MEMS micro movers are important parts of several types of MEMS devices including probe storage, cell sorters, optical MEMS and others. For example, probe storage memory devices use two parallel plates that carry a set of read-write heads (typically AFM tips) on one plate and a memory media on the other plate. At least one of the plates should be moved with respect to the other one in lateral X-Y plane while maintaining accurate control of the Z-spacing between the plates. Therefore, probe storage memory devices require a micro-mover to move at least one of the plates and allow scanning of memory media and data transfer by the read-write heads. Such motion enables each read-write head to access an area equal to the product of the range of relative X- and Y-motion. Tight spacing control between the two plates is necessary to: (a) eliminate mechanical contact between two plates; (b) maintain some required for data transfer parameters at the interface between the read-write heads and the memory media, for example, contact force and/or electrical resistance; (c) optimize life time of the read-write heads and memory media stack.

In many applications it is beneficial to have a large range of motion provided by a micro mover. For example, in probe storage devices required area covered by memory media is determined by the required memory capacity, pitch between the memory cells, number of bits stored in each of the memory cells, and formatting overhead. As each of the read-write heads can access an area equal to the product of the relative X- and Y-motion, the required number of read-write heads is determined by the ratio of the area covered by memory media and area accessed by one head. Required number of read-write heads can be in the range of thousands or even tens of thousands. Therefore, increasing range of motion for each read-write head allows decreasing their number and, consequently, overall complexity of the memory device.

### BRIEF DESCRIPTION OF THE DRAWINGS

Further details of the present invention are explained with the help of the attached drawings in which:

FIG. 1A is plan view of an embodiment of a bonded chip assembly with a MEMS micro-mover for use in positioning a movable plate relative to a stationary portion in accordance with the present invention.

FIG. 1B is a cross-sectional side view of the bonded chip assembly with a MEMS micro-mover of FIG. 1A.

FIG. 1C is a cross-sectional side view of a partially processed cap wafer for use in forming the bonded chip assembly with a MEMS micro-mover of FIG. 1A.

FIG. 1D is a cross-sectional side view of a partially processed plate wafer for use in forming the micro-mover of FIG. 1A.

FIGS. 2A and 2B are cross-sectional side views of an alternative embodiments of a bonded chip assembly with a MEMS micro-mover for use in positioning a movable plate relative to a stationary portion in accordance with the present invention.

FIG. 3A is a plan view of an embodiment of a coil for use with bonded chip assemblies with a MEMS micro-mover in accordance with the present invention.

FIG. 3B is a plan view of a magnet structure for use with the embodiment of FIG. 1A.

FIG. 3C is a cross-sectional side view of the magnet structure of FIG. 3B.

FIG. 4 is an exploded view of an embodiment of an assembly for use in probe storage devices in accordance with the present invention.

FIGS. 5A and 5B are embodiments of suspension arrangements for use with micro-movers in accordance with the present invention.

FIGS. 6A through 6D are cross-sectional side views of embodiments of movable plates for use with micro-movers in accordance with the present invention.

FIGS. 7A through 7C are cross-sectional side views of wafer stacks illustrating bending characteristics.

FIGS. 7D and 7E are cross-sectional side views of embodiments of movable plates for use with micro-movers in accordance with the present invention.

FIG. 8A is plan view of an alternative embodiment of a micro-mover having posts associated with the movable plate.

FIG. 8B is a cross-sectional side view of the micro-mover of FIG. 8A.

FIGS. 9A through 9D are cross-sectional side views of a movable plate of a wafer stack in various stages of processing.

FIG. 10A is a plan view of an embodiment of a capacitive sensor having two electrodes in accordance with the present invention.

FIG. 10B is a plan view of an embodiment of a capacitive sensor having three electrodes in accordance with the present invention.

FIG. 11A is a plan view of an embodiment of a micro-mover having capacitive sensors.

FIG. 11B is a part of a capacitive position sensing circuit.

FIGS. 12A through 12D are cross-sectional side views of a wafer stack having a single cap and actuator coils formed after bonding of the cap and plate wafers in various stages of processing.

FIGS. 13A through 13D are cross-sectional side views of a wafer stack having a single cap in various stages of processing according to an alternative embodiment.

FIGS. 14A through 14E are cross-sectional side views of a wafer stack having a single cap in various stages of processing according to still another embodiment.

FIGS. 15A through 15G are cross-sectional side views of a probe storage device employing a micro-mover in various stages of processing.

### DETAILED DESCRIPTION

Embodiments of stage stacks in accordance with the present invention can be employed in several types of MEMS including probe storage devices, cell sorters, optical systems, and other devices. For example, a cell sorter wherein healthy and sick cells having different characteristics are caused to migrate due to stimulation. While stage stacks are described particularly with regard to probe storage applications wherein a media device is positioned relative to a plurality of contact probe tips, embodiments of stage stacks for forming micro-movers for still other applications are intended to be within the scope of the present invention.

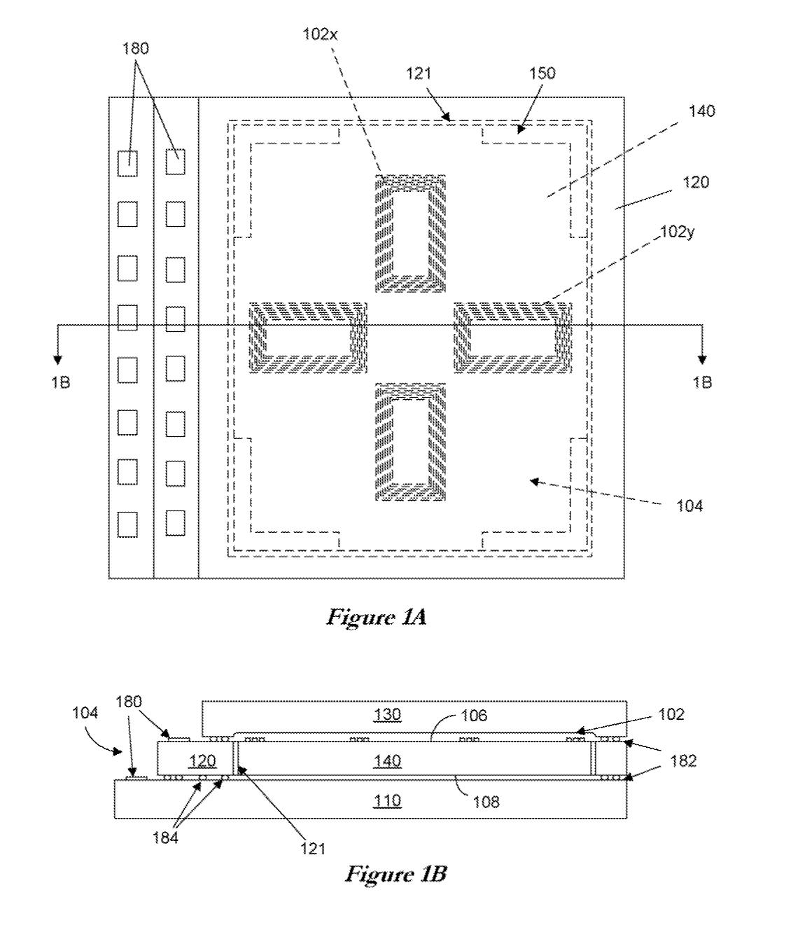

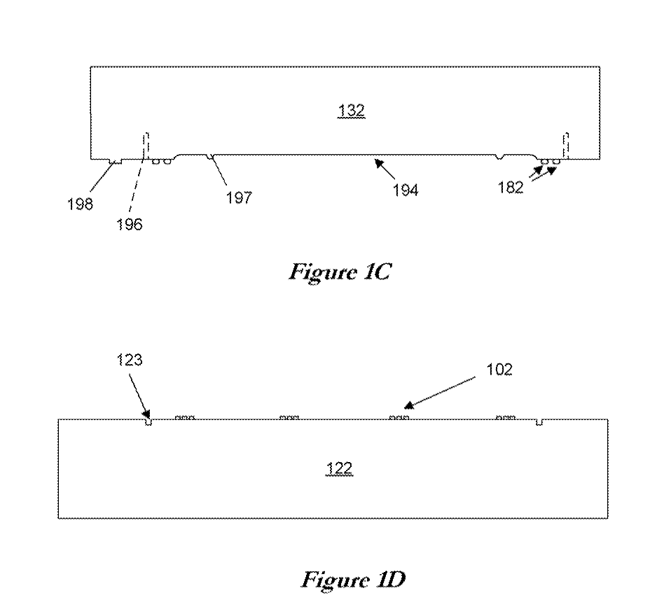

Referring to FIGS. 1A and 1B, an embodiment of a stage stack for a micro-mover for use with one of myriad different applications is illustrated. As can be seen, the stage stack 100 includes a bottom cap 110, a plate layer 104 and a top cap 130. The plate layer 104 is also referred to herein as a “plate wafer”, for example where wafer-level process steps are described. The plate layer 104 comprises a stationary portion 120 and a movable plate 140. The movable plate 140 and the stationary portion 120 have two principal surfaces: the first principle surface 106 facing the top cap 130 and the second principle surface 108 facing the bottom cap 110. Preferably, a suspension arrangement connected between the stationary portion 120 and the movable plate 140 allows motion of the movable plate 140 within a X-Y Cartesian plane. Range of motion is chosen depending on application. For example, in a preferred embodiment a micro mover for probe storage device, can enable displacement of the movable plate 140 in the range of 20 to 200 μm. Preferably, an actuator provides bi-directional motion of the movable plate 140 along both transverse (Y) and lateral (X) axes of the X-Y Cartesian plane.

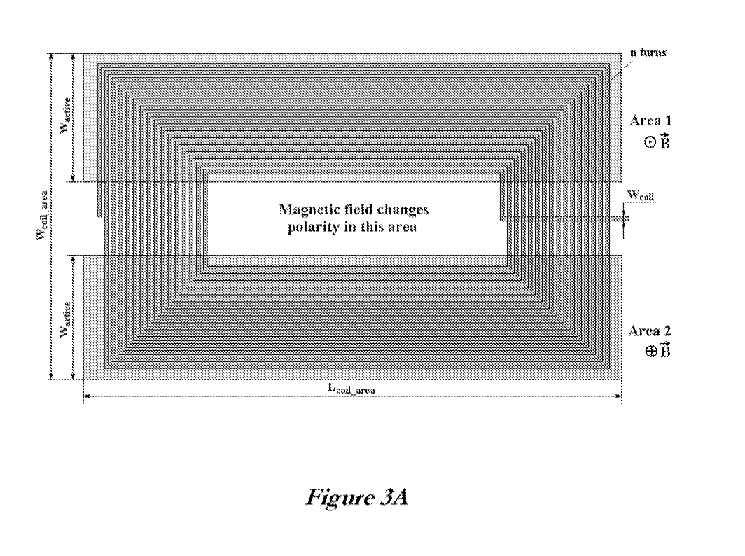

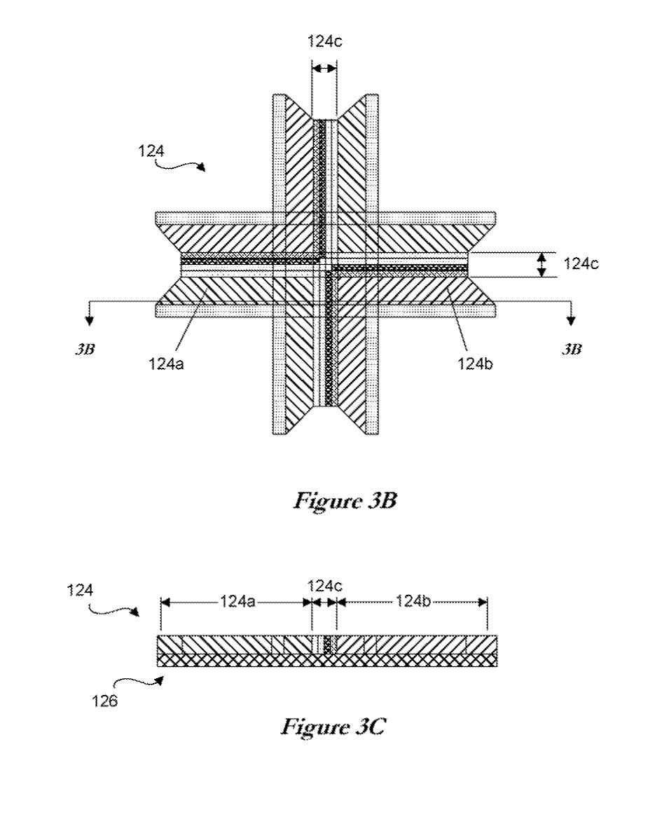

The movable plate 140 can be urged in the X-Y Cartesian plane by taking advantage of Lorentz forces generated from current flowing in a conductor when a magnetic field perpendicular to the X-Y Cartesian plane is applied across the conductor current path. Preferably, coils can be used in order to provide force for moving the movable plate 140. At least one coil 102 can be placed on the movable plate 140. In order to provide 2D motion of the movable plate the coils can be arranged in a cross configuration (as shown particularly in FIG. 3), and can be formed such that the movable plate is disposed between the coils and an accessible surface of the movable plate (e.g. fixedly connected with a back of the movable plate the movable plate 140 can have X and Y axes of symmetry and the coils can be arranged symmetrically about these axes, with one pair of coils 102x comprising an actuator for urging the movable plate in a lateral (X) direction within the Cartesian plane, and the other pair of coils 102y comprising an actuator for urging the movable plate in a transverse (Y) direction within the Cartesian plane. The coils 102 allow coarse positioning of the movable plate 140. In some embodiment, the movable plate 140 can further include additional coils (not shown in FIGS. 1A and 1B) for fine positioning of the movable plate 140.

Depending on application, movable plate 140 can perform different functions. For example, the movable plate 140 can be used to move objects, to store data, to reflect radiation, etc. Either one or both principle surfaces 106, 108 of the movable plate 140 can be used to perform the required function. The principle surface used to perform a required function is referred later as a functional surface of the movable plate 140. In some applications, presence of the coil on a functional surface of the movable plate is allowable. For example, if the micro-mover is used to move small objects and these objects are not affected by the voltage and the current in the coils 102 then the principle surface of the movable plate 140 with the coil can serve as a functional surface. However, in some applications presence of the coil on the functional surface is undesirable. For example, in probe storage devices the functional surface of the movable plate 140, preferably, is made very smooth to allow high-speed probe scanning and avoid damage of cantilevers and contact probe tips during scanning the memory media. Coil represents a profile on the surface and, therefore, if coils are located on the functional surface then the area occupied by the coils can not be used for storing data. In such applications coil can be located on the principle surface of the movable plate 140 opposite to the functional surface. In this case utilization of the surface of the movable plate 140 need not be affected by the coil layout. In other embodiments the coils can be formed on the functional surface of movable plate 140. In such embodiments, a portion of the surface of the movable plate 140 will be dedicated to the coils, reducing surface utilization of the movable plate.

The four coils 102 can be formed or otherwise disposed on a first surface of the movable plate layer 140 and can comprise multiple windings. Coils can be disposed on either one of principle surfaces 106, 108 of the movable plate (as shown in FIG. 1B) or on an opposite side of the movable plate 140. Preferably the coils 102 can comprise an equal number of windings having approximately the same trace cross-section and pitch, though in other embodiments the cross-section and pitch can vary, so long as a desired relative movement between the movable plate 140 and the cap 130,110 can be achieved with a desired control. In still other embodiments, it may be desired that movement in only one of the transverse and lateral axes be enabled, thereby necessitating alternative coil arrangement.

The stage stack as shown has a tiered arrangement so that a portion of the bottom cap 110 and the plate layer 104 can include bond pads 180 on exposed surface of the corresponding component. Bond pads 180 are easily formed by well known semiconductor processes. The bond pads 180 enable electrical communication with circuits formed within the corresponding component. Electrical connections are made using wire bonding to the bond pads located on the stationary portion 120 of the plate layer 140 and on the bottom cap 110. In other embodiments, electrical communication can be achieved through some other structure, such as a vertical, conductive structure formed along a peripheral z-axis edge of the component.

A gap 121 can exist between the movable plate 140 and stationary portion 120 of the plate layer 104. The movable plate 140 can have a range of motion approximating the width of the gap 121 in any direction. The suspension structure 150 further suspends the movable plate 140 at a substantially uniform distance from the bottom cap 110 (i.e. without substantial out-of-plane shift or bending). The distance between the movable plate 140 and the bottom cap 110 can approximately correspond with a distance between the stationary portion 120 of the plate layer 104 and the bottom cap 110, which can be defined by a thickness of a bond ring 182 disposed between the stationary portion 120 and the bottom cap 110 for causing the stationary portion 120 and the bottom cap 110 to be fixedly connected.

Electrical components, for example IC circuits, (not shown in FIG. 1) can be formed on the second principle surface 108 of the movable plate 140 and/or stationary portion 120. In this case it can be desired that some of the electrical lines (not shown in FIG. 1) connected to these components be transferred from the second principle surface of the movable plate 140 and/or stationary portion 120 either to the bottom cap 110 or to the first principle surface 106 of the stationary portion 120. Electrical lines from the movable plate 140 can be transferred to the stationary portion 120 with help of conductive bridges. As it is discussed in more details below, the conductive bridges can be made by different means, including: (a) metal lines formed on top of suspension flexures 150, (b) metal lines formed on top of additional flexible structures connecting the movable plate 140 and the stationary portion 120; said additional flexible structures can have a significantly smaller bending stiffness than the suspension flexures; and (c) metal bridges connecting the movable plate 140 and the stationary portion 120. Where the wafer bonding process utilizes metal or metal alloy as a bonding material, the electrical lines can be transferred from the stationary portion 120 of the plate layer 104 to the bottom cap 110 using the conductive connectors 184 within the gap between the stationary portion 120 and the bottom cap 110. The body of the stationary portion 120 of the plate layer 104 and the body of the bottom cap 110 can further be electrically connected by way of common electrical contact 184 within the gap between the stationary portion 120 and the bottom cap 110.

The top cap 130 is fixedly connected with the stationary portion 120 of the plate layer 104 by way of a bond ring 182 or set of bond rings. The volume between the bottom cap 110 and the top cap 130 within which the movable plate 140 is entirely disposed can be hermetically sealed to prevent contamination and interference with the movement and operation of the movable plate 140 and/or structures adapted to interact with the movable plate 140. The bottom and top caps 110, 130 provide mechanical and environmental protection of the movable plate 140. The bottom and top caps 110, 130 are bonded to the plate wafer 104 at the wafer level. Preferably, hermetic wafer bonding process is used. The wafer bonding process, preferably, allows the transfer of electrical signals between the plate layer 104 and the caps. The bonding gap between the movable plate 104 and the caps is small and well-controlled by the wafer bonding process. As described in further detail below, a thin layer of gas between the movable plate 140 and the caps 110, 130 can provide dampening of vertical motion of the movable plate 140 due to a squeeze film effect.

Referring to FIG. 1C, a partially processed top cap wafer 132 is shown. The top cap wafer 132 can comprise silicon. The partially processed top cap wafer 132 has a cavity 194 formed within a portion of the top cap 130 disposed over the principle surface 106 of the movable plate 140 after bonding of the cap wafer 132 and a plate wafer 104. The cavity 194 prevents mechanical contact and sticking of the movable plate 140 and/or suspension arrangements 150 to the top cap 130. The cavity 194 is wider than the movable plate 140 to account for the maximum displacement of the movable plate 140. If the suspension arrangement 150 connected between the stationary portion 120 of the plate layer 104 and movable plate 140 has either initial bending or vertical displacement during operation, then a stepped profile of the shallow cavity can accommodate the bending or vertical displacement of the suspension arrangement 150. In some embodiments, a thickness of the bonding ring 182 is sufficient to ensure that no mechanical contact occurs between the movable plate 140 and the top cap 130 under normal operating conditions, thereby rendering the cavity 194 superfluous.

In some embodiments, the cap wafer 132 can comprise small-area stops 197 extending within the cavity 194 for resisting vertical and/or rocking motion of the movable plate 140. The small-area stops 197 further reduce a risk that the movable plate 140 will adhere or contact a surface of the top cap 130. Preferably, the small-area stops 197 are located near the periphery of the cavity 194, although optionally one or more small-area stops 197 can extend from approximately the center of the cavity 194. The number of small-area stops 197 can be limited, for example to four or five in number, while satisfactorily resisting sticking of the movable plate 140 to the top cap 130. The movable plate 140 does not contact the small-area stops 197 under normal operation conditions, but rather contact occurs during shock events. It is estimated that a top cap 130 having four stops disposed along the periphery of the cavity 194 can expect to experience contact between the movable plate 140 and one or more small-area stops 197 when a rocking motion occurs, while expecting contact between the movable plate 140 and substantially all of the small area stops 197 when the micro-mover is loaded by a vertical acceleration. In other embodiments, small-area stops can be located on the movable plate 140 in substitution of, or in addition to small-area stops 197 extending from the top cap 130.

Multiple different bonding techniques can be employed to fixedly associate the top cap wafer 132 with the plate wafer 104. The bottom and top caps 110, 130 are preferably bonded to the plate wafer 104 at wafer level using low-stress, low-temperature bonding. At least some bonding techniques require the presence of bonding material on both the top cap wafer 132 and the plate wafer 104 (e.g. thermo-compression bonding, solder bonding). In still other bonding techniques, bonding material need only be deposited on one of the top cap wafer 132 and the plate wafer 104 (e.g. polymer bonding, adhesive bonding, bonding with frit glass, bonding with help of eutectic compositions). Where bonding material is deposited on both the top cap wafer 132 and the plate wafer, the bonding material can be patterned to help ensure alignment of the first and second bonding material. Preferably, a bonding pattern comprises one or more bond rings 182 (two as shown in FIG. 1C) arranged so that the suspension arrangement 150 and movable plate 140 are disposed within the bonding pattern.

Optionally, the top cap wafer 132 can further include dicing grooves 196. The dicing grooves 196 are arranged so that bonding pads of one or both of the stationary portion 120 of the plate layer 104 and the bottom cap 110 are exposed when processing electrical connections is desired. The use of dicing grooves 196 can simplify the process of removing a part of the top cap wafer 132 without undesirably damaging metal lines and/or the bond pads of an underlying wafer, access to which is desired. These removed parts are also referred to herein as “pad expose cuts”. Optionally, additional grooves can be formed along the saw lines, simplifying dicing of the wafer stack during processing.

Still further, in some embodiments it can be desired that one or more dead stops 198 extend from one or both of the top cap wafer 132 and the plate wafer 122 for controlling a height of a bonding gap between the wafers. During bonding, the bonding material can experience squeezing due to one or more of softening, melting, or otherwise undergoing a change in rigidity, combined with pressure applied to the stack of wafers. The bonding gaps between the cap wafers and the plate wafer can decrease until a physical limit is reached with the dead stops 198 contact an opposing surface. The bonding gap can be fixed in relative position when the physical limit is reached. The bonding gap height is thus determined by the height of the dead stops 198.

A target bonding gap between the wafers can be small, depending on the application for which the micro-mover is used. In some embodiments a height of the one or more dead stops 198 can have a range as small as 0.5 um to 2 um. The one or more dead stops 198 can be formed using myriad different techniques. One such technique for forming dead stops 198 having a precise height employs semiconductor processing to form dead stops 198 out of a thin film layer or a stack of thin film layers. For example, dead stops 198 can be formed from thermal oxide. The thickness of a thermal oxide film can be controlled with nanometer-range accuracy.

Referring to FIG. 1D, a partially processed plate wafer 122 is shown. At least one coil 102 is formed on the plate wafer 122. As described above, preferably the plate wafer 122 includes at least four coils disposed on a targeted part of the plate wafer 122 which when processed becomes a movable plate 140. In a preferred embodiment, the coils 102 can be formed on the plate wafer 122 before the plate wafer 122 is bonded to a cap wafer 110,132. In other embodiments, the coils 102 can be formed after the plate wafer 122 has been bonded to the cap wafer 110,132 and the plate wafer 122 has been thinned. As shown, the partially processed plate wafer 122 further includes shallow cavities 123 that can define the shape of suspension flexures and other components of the suspension arrangement 150. In particular, the shallow cavities 123 can define the location of bridges carrying metal lines connecting the movable plate 140 and the stationary portion 120. In a preferred embodiment, the plate wafer 122 can comprise monocrystalline silicon. Use of monocrystalline silicon enables the movable plate 140 to have a flatness within desired tolerances and a suspension arrangement 150 substantially free from stress (thereby reducing out of plane bending of the suspension arrangement 150 and vertical shift of the movable plate 140).

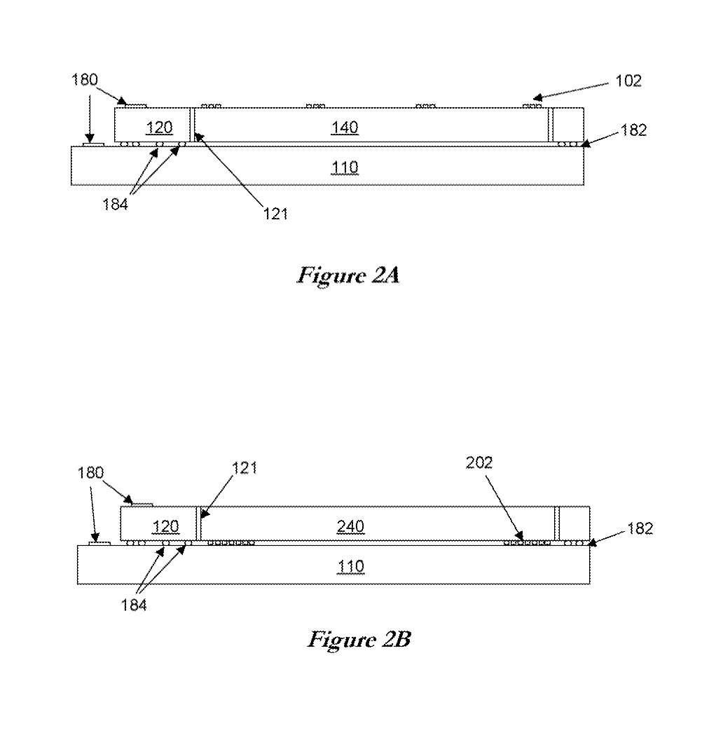

Referring to FIGS. 2A and 2B, alternative embodiments of micro-movers can include a stage stack comprising a bottom cap 110 and a plate layer, wherein the plate layer comprises a stationary portion 120 and a moving plate 140,240. As above, coils 102 can be formed on the first principle surface of the movable plate 140, as shown in FIG. 2A, or coils 202 can be formed on the second principle surface of the movable plate 240, as shown in FIG. 2B.

Electrical components, for example IC circuits, (not shown in FIG. 2) can be formed within the plate layer. When coils 102 and electrical components are formed on the first principle surface of the plate layer external electrical connection to them can be provided with help of bond pads 180 located on the stationary portion 120 of the plate layer. Coils and other electrical components located on the movable plate 140 can be connected to the stationary portion 120 with help of conductive bridges. Conductive bridges can be made by different means, including: (a) metal lines formed on top of suspension flexures, (b) metal lines formed on top of additional flexible structures connecting the movable plate 140 and the stationary portion 120; said additional flexible structures can have a significantly smaller bending stiffness than the suspension flexures; and (c) metal bridges connecting the movable plate 140 and stationary portion 120.

If coils 102 and electrical components are formed on the second principle surface of the stationary portion 120 of the plate layer and the movable plate 240 then it can be desired that some of the electrical lines (not shown in FIG. 2) connected to these components and to the coils 102 be transferred from the second principle surface of the plate layer either to the bottom cap 110 or to the first principle surface of the plate layer. As it was discussed above, electrical lines from the movable plate 140 can be transferred to the stationary portion 120 with help of conductive bridges. Transferring of electrical lines from the second principle surface of the plate layer to the bottom cap 110 can be done using a conductive bonding material.

Referring to FIG. 3A, a coil for use with embodiments of micro-movers in accordance with the present invention is shown. In a preferred embodiment, a magnetic field co-axial with a coil includes opposite orientations in areas 1 and 2 of the coil. Areas 1 and 2 are two active areas where the Lorentz force is generated. The magnetic field can change polarity between areas 1 and 2. Preferably, the design of the coil should provide sufficient force to urge the movable plate within the magnetic field across a desired range of motion, and at a desired acceleration. Further, preferably the coil meets application requirements for power consumption and bending tolerances of the movable plate over an operating temperature range.

A coil having n turns will generate a maximum actuator force, Fₚₑₐₖ, according to the equation:

Fₚₑₐₖ≧Iₘₐₓ·B·n·l_{active}

where B is the average magnetic field in the active areas, Iₘₐₓ is the maximum current in the coil and active is the average length of the active segment generating the force. The above formula assumes that magnetic field B has the same average magnitude and opposite directions in active areas 1 and 2. Preferably, the maximum actuator force should be at least as sufficient as the minimum force required to achieve the required maximum displacement at a desired maximum acceleration.

The maximum acceleration of the movable plate provided by the actuator is:

$${a}_{peak} \geq \frac{{F}_{peak}}{{M}_{plate}} = \frac{{I}_{max} \cdot B \cdot n \cdot {l}_{active}}{{ρ}_{Si} \cdot λ \cdot {L}_{plate} \cdot {W}_{plate} \cdot {t}_{Si}}$$

where Mₚₗₐₜₑ is the mass of the movable plate, ρ_{Si} is the density of silicon, λ·Lₚₗₐₜₑ·Wₚₗₐₜₑ is the area of the movable plate with Lₚₗₐₜₑ and Wₚₗₐₜₑ corresponding to the length and width of the movable plate and λ is a coefficient corresponding to the portion of the movable plate less the suspension arrangement.

Power dissipated by the electromagnetic actuator, i.e. by the coils 102, is another important parameter of the micro-mover. Some application can have either peak power or average power limitations or both. For example, using micro-mover in the portable devices can put some limitations of the power dissipated by the micro-mover. The peak power Pₚₑₐₖ dissipated by one coil is equal to:

$${P}_{peak} = {I}_{max}^{2} \cdot {R}_{coil} = {I}_{max}^{2} \cdot {ρ}_{coil} \cdot \frac{{I}_{coil}}{{w}_{coil} \cdot {t}_{coil}} ,$$

where ρ_{coil}—resistance of the coil material; l_{coil}, w_{coil}, and t_{coil}—length, width, and thickness of the coil wire, correspondingly.

Bending of the movable plate due to bimetallic effect caused by the presence of the coil and some dielectric layers on the movable plate should be considered in some micro-mover applications, for example, in probe storage devices. An increase in an amount of metal on the movable plate can cause an increase in bending of the movable plate.

Coil design can be affected by the maximum current density allowable in the coil and/or by the maximum power that can be dissipated by the micro-mover. Coil design can benefit from accounting for one or more of the following parameters:
a) Coil design can target maximizing either the peak force or the average force generated by the coils. Alternatively, coil design can target maximizing either the peak acceleration or other kinematical parameter of the movable plate motion (e.g. the average speed of the movable plate). It can be assumed that coils are located in a uniform magnetic field perpendicular to the coil plane and having induction magnitude of B.
b) Four coils can be located on the same side of the movable plate symmetrically with respect to the lateral (X) and transverse (Y) axes of the movable plate. As shown in FIG. 1A, two coils can be aligned along the lateral axis (X) and two coils can be aligned along the transverse axis (Y). Where the movable plate 140 does not have X and Y symmetry axes, a position of the coils can be determined by the position of inertia axes of the movable plate. Namely, two coils can be aligned along the projection of the lateral axis of inertia (X) on the surface of the movable plate and two other coils can be aligned along the projection of the transverse axis of inertia (Y) on the surface of the movable plate. Coils aligned along an X axis have the same geometry. Coils aligned along a Y axis also have the same geometry. An area occupied by the coils is limited by their mutual arrangement. To improve motor efficiency the coils may be placed diagonally across the corners of the moveable stage. Magnet placement should correspond with coil placement so that the magnetic field is substantially aligned with the coils.
c) A maximum current density in the coil can be limited by the reliability requirements related, in particular, by electromigration of coil material.
d) One of the maximum peak power and the maximum average power dissipated by one coil can be limited due to power limitations for the micro-mover.
e) A maximum voltage available for one coil can be limited due to limitations on the micro-mover supply voltage.
f) A maximum bending of the movable plate due to bimetallic effect can be limited due to limitations on the gap width between the movable plate and the caps.

For applications where bending of the movable plate due to bimetallic effect is not important, it can be desirable to increase both the thickness of the coil metal as well as the width of the coil wire and number of turns. Preferably, a cross-section of the coil can be chosen roughly the same as a cross-section of a metal line connecting the coil with the stationary portion.

In applications where bending of the movable plate due to bimetallic effect can be a limiting factor, the amount of metal can be problematically increased where one or more of the width w_{coil} or thickness t_{coil} of the coil wire is increased, or where an average length 1_{average} of the turn is increased. Given the equation:

$${δ}_{max} = A \cdot \frac{{t}_{coil}}{{t}_{Si}^{2}} \cdot n \cdot {w}_{coil} \cdot {l}_{average}^{2} .$$

where A is a coefficient, which does not depend on coil wire width and thickness, but depends on coil and plate geometry and working temperature range; and δₘₐₓ is the maximum allowable bending of the movable plate, it is possible to determine a geometry of a coil that produces a bending of the movable plate within the desired tolerance. If flatness of the movable plate is a concern, then thickness of the movable plate should be significantly larger than a thickness of the coil. A minimum thickness t_{Si} of the movable plate for a given coil design can be defined to satisfy bending requirements given a geometry of the coil and the following formula:

$${t}_{Si} = \sqrt{A \cdot \frac{{t}_{coil} \cdot n \cdot {w}_{coil}}{{δ}_{max}}} \cdot {1}_{average} .$$

### In a preferred embodiment, the micro-mover can operate at a maximum current density allowable for the coil metal in order to minify an amount of metal on the plate and consequently the amount of bending of the movable plate.

Maximum actuator force can be increased by increasing one or both of a thickness of the coil, t_{coil}, and a product of the number of turns n and the width of the coil wire w_{coil}. However, a corresponding increase in the plate thickness t_{Si} can result in an increase in suspension stiffness. Suspension flexures can have substantially the same thickness as the plate wafer from which they are is formed. A bending stiffness of the suspension arrangement in the direction of actuation is directly proportional to the thickness of the movable plate. Some micro-machining process techniques (e.g. reactive ion etching (RIE)) can limit an aspect ratio of the suspension flexures (flexure thickness to width ratio) obtainable with satisfactory reproducibility. The bending stiffness of the suspension is proportional to the third power of the width of the suspension flexure. Therefore, increasing the thickness of the movable plate can cause at least a linear increase in the bending stiffness when the width of the suspension flexure is maintained. If the width of the suspension flexures is increased proportionally to the thickness of the movable plate, the bending stiffness of the suspension is increased proportionally to the fourth power of the thickness of the movable plate.

There are two competing factors affecting the maximum acceleration of the movable plate due to an increase of cross-section of the coil wire: (a) a decrease in coil resistance tends to increase coil current and actuator force and, therefore, maximum acceleration; and (b) an increase of movable plate thickness increases mass and decreases the maximum acceleration provided by the actuator decreases. After reaching the limit of the plate bending, a further increase of the width of the coil and number of turns in the coil, as well as an increase in thickness of the coil does not provide an increase of the maximum acceleration due to an increase in mass of the movable plate. One coil design option is based on using such cross-section of the coil wire that carries the maximum allowable current density when the maximum voltage is applied to the coil.

As mentioned above, in some applications of micro-movers it is beneficial to use a two-stage actuator. A coarse actuator can be used for one or both of large displacements (in the range of microns or tens of microns) and relatively fast acceleration of the movable plate. A fine actuator can be used for achieving sub-nanometer positional accuracy and/or resolution. For example, if a stiffness of the suspension arrangement is 20 N/m and a coarse actuator utilizing two coils with n=14 turns with average active length of (active=6 mm, having the maximum coil current of 10 mA is used in a magnetic field of B=0.4 T then the coarse actuator can provide the maximum force of approximately 0.67 mN and the coarse actuator is capable of providing movable plate displacement of about 33 μm. A fine actuator consisting of a wire with an active length of 6 mm and maximum current of 1 mA can provide a maximum force of 2.4 μN, which is capable of providing movable plate displacement of about 120 nm. Assuming that the coarse actuator current is controlled within ±10 mA by a 12-bit DAC, its least significant bit (LSB) corresponds to about a 5 μA current increment and about 16 nm displacement increment. The fine actuator controlled by a 10-bit DAC has LSB corresponding to 2 μA current increment and 2.4 Å displacement increment.

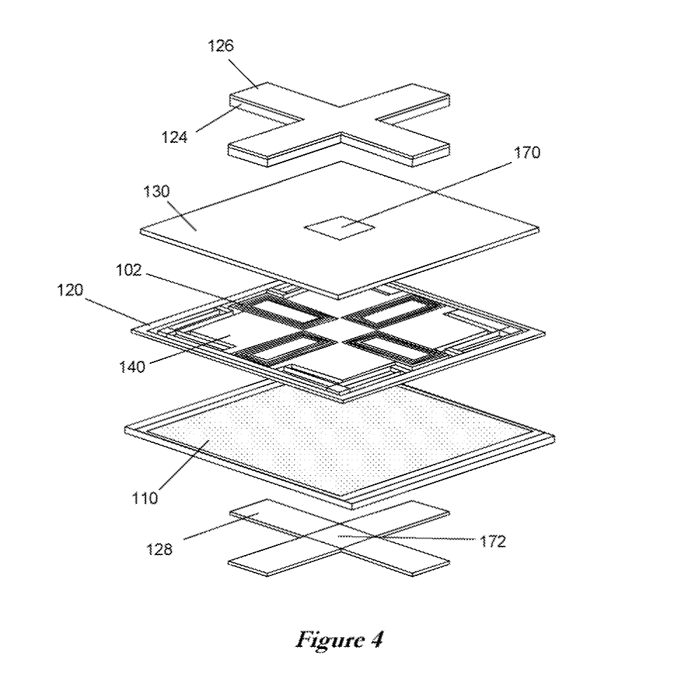

The actuator of the micro-mover can be completed by a magnetic field generated at least across the coils 102. For example, the magnetic field can be generated by a permanent magnet associated with one or both of the top cap 130 and the bottom cap 110. The permanent magnet can be integrally formed with the corresponding micro-mover die structure 110, 130, or alternatively can be affixed to the corresponding structure 110, 130. Lorentz force generated by the coil current in a magnetic field is used to urge the movable plate 140 within the X-Y Cartesian plane relative to the stationary portion 120. Alternatively, the permanent magnet can be integrated with the parts of the package. Referring to FIGS. 3B and 3C, the permanent magnet 124 can be fixedly connected with a rigid structure such as a steel plate 126 that generally maps the permanent magnet 124 to form a magnet structure. Referring to FIG. 4, a second steel plate 128 generally mapping the permanent magnet 124 can be arranged so that the top and bottom caps 110, 130 movable plate 140, and coils 102 are disposed between the magnet structure and the second steel plate 128. The magnetic flux is contained within the gap between the magnet structure and the second steel plate 128. In alternative embodiments, a pair of magnets can be employed such that the stages and coils are disposed between dual magnets, thereby increasing the flux density in the gap between the magnets. The minimum thickness of some strong permanent magnets can be limited due to mechanical properties of the magnet material. Therefore, thickness of the permanent magnet can be bigger than thickness of the steel plate 126, 128. As a result, a device utilizing a micro mover with two permanent magnets can be thicker than a device utilizing a micro mover with one permanent magnet. However, the device utilizing two permanent magnets can provide either smaller power consumption for the same speed, maximum displacement of the movable platform and actuation force or higher speed, bigger maximum displacement of the movable platform, and larger actuation force for the same power consumption. The force generated from the coil 102 is proportional to the flux density, thus the required current and power to move the movable plate 140 can be reduced at the expense of a larger package thickness.

Where the micro-mover is employed for probes storage applications, there is a possibility that a write current could disturb the movable plate due to undesirable Lorentz force. However, for probe storage devices having media devices comprising phase change material, polarity dependent material, or other material requiring similar or smaller write currents to induce changes in material properties, movable plate movement due to write currents can be sufficiently small as to be within track following tolerance. In some embodiments, it can be desired that electrical trace layout be configured to generally negate the current applied to the contact probe tip, thereby minifying the affect.

FIGS. 3B and 3C illustrate a preferred embodiment of a magnet north-south arrangement in a single magnet system for use in probe storage devices in accordance with the present invention. As can be seen, a portion 124a of the magnet 124 can have a north orientation, while a substantially symmetrical portion 124b of the magnet 124 can have a south orientation. Disposed between the north oriented portion 124a and the south oriented portion 124b is a transition zone 124c comprising gradual changes in magnet orientation from north to south and south to north. In other embodiments, the magnet 124 need not have a north-south arrangement as shown in FIG. 3B, but must merely be magnetized such that a desired magnetic flux density be achieved in the gap between the magnet structure and the second steel plate 128. Thus, in other embodiments, some other north-south arrangement in a magnet can be employed.

FIG. 4 shows an exploded view of an embodiment of a stage stack 100 for use in a probe storage device in accordance with the present invention. The stage stack 100 includes a first steel plate 126 bonded to a permanent magnet, for example Sm—Fe—N magnet, 128 to form a magnet structure. The magnet structure is bonded to a silicon cap 130. A second steel plate 128 is bonded to a back surface of a bottom cap 110. A movable plate 140 is disposed between the bottom cap 110 and the silicon cap 130. As described below, the movable plate 140 can comprise a silicon-on-insulator (SOI) structure. A stationary portion 120, with which the movable plate 140 is connected, is bonded to the bottom cap 110 by way of a bond ring. The bond ring can comprise, in an embodiment, an indium based solder, other material based solder, Au—Sn or Au—In eutectic ring of some small, substantially uniform thickness disposed along the periphery of one or both of the stationary portion 120 and the bottom cap 110. The stationary portion 120 and the bottom cap 110 are fixed in position relative to one another by the bond; however, the movable plate 140 can move relative to the stationary portion 120 and the bottom cap 110 by way of flexures connecting the stationary portion 120 with the movable plate 140.

It can be desirable to dedicate as large a portion of the movable plate as possible to application utilization (e.g. probe storage devices). To achieve increased utilization it can be desired to reduce the percentage of the movable plate area dedicated to a support structure and/or suspension arrangement. If a suspension arrangement of the movable plate suspension requires significant area, the area utilization of the device will be correspondingly limited. A movable plate that is movable is susceptible to damage from dynamic events such as shock and vibration. Embodiments of suspension arrangements and movable plate in accordance with the present invention can increase utilization while improving shock response.

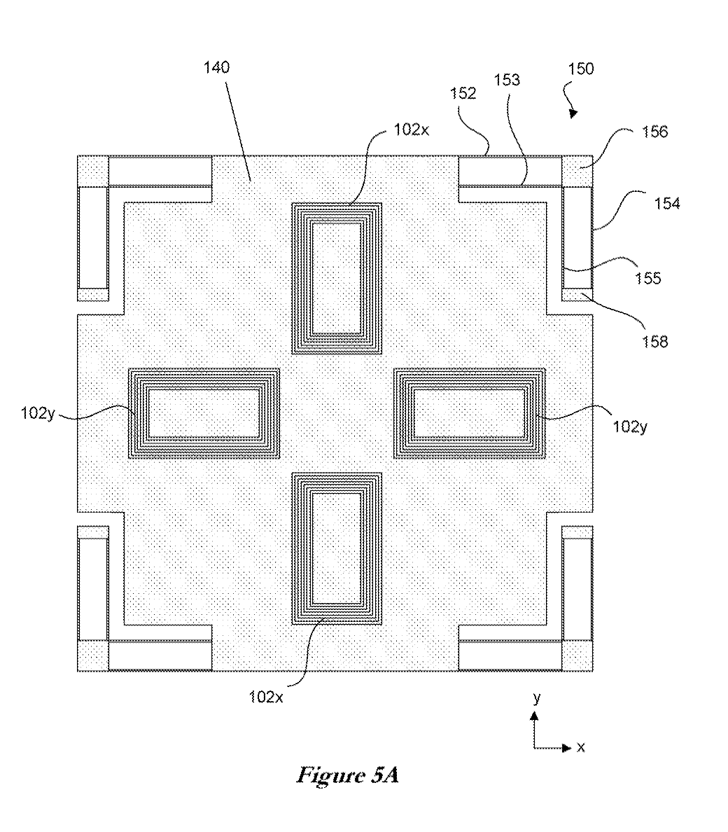

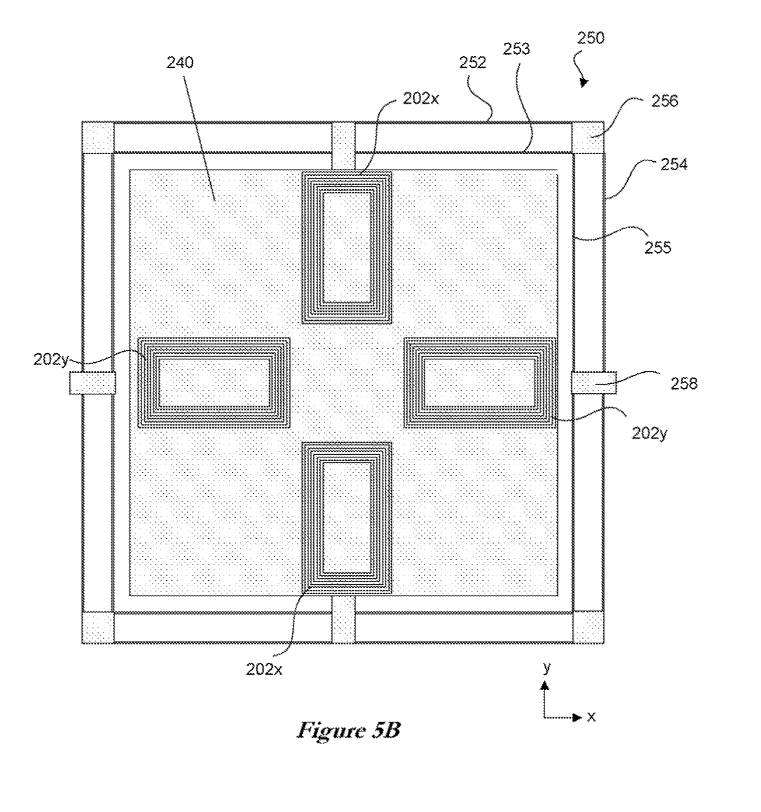

Referring to FIG. 5A, an embodiment of a suspension arrangement for a movable plate in accordance with the present invention is shown. The suspension arrangement comprises multiple “L-shape” suspensions of mutually perpendicular flexures. As shown, an “L-shape” suspension comprises a first pair of flexures 152, 153 extending from the movable plate to a knee 156 of the suspension arrangement 150. A second pair of flexures 154, 155 extends from the knee 156 perpendicular to the first pair of flexures 152, 153 to a foot 158 of the suspension arrangement 150. The foot 158 can be fixedly connected with a stationary portion 120 of the plate layer, as shown in FIG. 4. The flexures 152-155 are arranged to provide relatively isolated X motion and Y motion. For example, if the movable plate 140 is moved with the two coils 102x aligned along the y-axis, movable plate 140 movement produces bending in the flexures 154, 155 connected between the knee 156 and the foot 158 (i.e. in the portion of the L-flexure that is parallel to the longest length of the coil 102x). The length of the flexures can be adjusted, shortening the length of the flexures to permit higher media utilization, and increasing the length of the flexures to reduce the power needed to generate motion. A balance can be struck between maximizing the media and minimizing the power.

The suspension arrangement 150 can be built by patterning and etching the plate wafer 140 using a deep RIE etcher. In a preferred embodiment, the suspension arrangement 150 can include flexures having height to width aspect ratios of 10:1. An example of flexures can be one having a width of 13.8 um and thickness (corresponding to a thickness of the movable plate) of 136 micron. Prior art flexures for use in electrostatic actuators and other movement devices typically include aspect ratios of 40:1. A smaller aspect ratio can reduce the relative suspension stiffness variation during manufacturing, decrease dynamic performance variation and increase yield.

The suspension arrangement 150 provides very high shock tolerance. Further, the mutually perpendicular flexures allow substantially isolated motion within the X-Y Cartesian plane while reducing cross-coupling. The rotational stiffness of the movable plate 140 can be adjusted by changing the spacing between flexure pairs. Narrow flexure spacing produces a lower rotational stiffness while wide flexure spacing produces higher rotational stiffness. The suspension arrangement of FIG. 5A consumes a small percentage of the movable plate 140, relative to suspensions arrangements of the prior art, allowing die area utilization for the movable plate 140 to be increased. This is especially important in memory applications, where memory capacity is directly proportional to the movable plate area.

Combining the suspension arrangement 150, coils disposed on one of the principle surfaces, memory media disposed on the other principle surface of the of the movable plate 140 and the described above magnetic circuit allows probe storage device with high area utilization. For example, on a 10 mm by 10 mm stage, the effective area utilization is expected to be close to 70%. Such a high rate of area utilization can allow for high capacity with a small package as compared to prior art designs of probe storage devices.

Referring to FIG. 5B, an alternative embodiment of a suspension arrangement 250 for a movable plate 240 in accordance with the present invention is shown. As with the previous embodiment, the suspension arrangement 250 comprises multiple “L-shape” suspensions of mutually perpendicular flexures. As shown, an “L-shape” suspension comprises a first pair of flexures 252,253 extending from the movable plate 240 to a knee 256 of the suspension 250. A second pair of flexures 254, 255 extends from the knee 256 perpendicular to the first pair of flexures 252, 253 to a foot 258 of the suspension arrangement 250. The foot 158 can be fixedly connected with a stationary portion 220. However, unlike the previous embodiment, adjacent suspension arrangements share a foot 258. The flexures 252-255 have longer lengths when compared with a movable plate as shown in FIG. 5A having the same dimensions. The increased length of the flexures results in lower media utilization when compared to the previous embodiment, but can result in a reduction in power needed to generate motion. The flexures 252-255 are arranged to provide relatively isolated X motion and Y motion. For example, if the movable plate 240 is moved with the two coils 202x aligned along the y-axis, movable plate 240 movement produces bending in the flexures 254,255 connected between the knee 256 and the foot 258 (i.e. in the portion of the L-flexure that is parallel to the longest length of the coil).

The present invention is not intended to be limited to suspension arrangements and/or movable plates as shown in the figures included herein, but rather the present invention is meant to include myriad different embodiments employing the underlying principles for arranging a movable plate as desired. One of ordinary skill in the art will appreciate the myriad different arrangements of flexures for movably connecting a movable plate with a stator such as a stationary portion.

Coils and possibly some other electrical components located on the movable plate can be connected to the stationary portion. Electrical connections can be made by placing metal lines on one or both sides of suspension flexures or by using additional flexible structures connecting the movable plate and the stationary portion. Where the metal lines providing the electrical connections are disposed along the suspension flexures it can be desirable to reduce out-of plane bending of the suspension flexures caused by metal disposed along the suspension flexures. Out-of-plane bending can be reduced by one or more of decreasing a cross-sectional area of the metal lines routed along the suspension flexures, disposing one or more dielectric layers between the metal lines and the body of the suspension flexures to compensate for out-of-plane bending that would otherwise result from metal lines due to the bimetallic effect, or placing metal lines both on the top and bottom of the suspension flexures.

In some embodiments, suspension flexures can be free of metal and minify an amount of dielectric deposited on the suspension flexures. Electrical connections between the movable plate and the stationary portion can be made with additional flexible structures. The additional flexible structures can comprise metal lines deposited on top of additional silicon flexures having a thickness substantially similar to the thickness of the movable plate. However, bending stiffness of the bridge structures can be made significantly smaller than bending stiffness of the suspension flexures. Alternatively, the additional silicon flexures can have a thickness smaller than the thickness of the movable plate so that the bending stiffness of the bridge structures is significantly smaller than bending stiffness of the suspension flexures. Alternatively, metal lines only or metal lines disposed over a dielectric layer can be employed having small X-Y bending stiffness.

In still other embodiments, number of bridge structures used for electrical connections between the movable plate and stationary portion can be reduced by using the substrate as a common electrode for some electrical components. For example, the substrate can be used as a ground electrode or as an electrode with the highest potential.

A thickness of the plate layer can be determined based on a plurality of factors including satisfying flatness requirements related to bimetallic bending and built-in stress associated with wafer processing, and enabling movement of the plate wafer through all steps of the fabrication process. Preferably, both the plate wafer and the suspension arrangements are fabricated from a stress-free material, for example, monocrystalline silicon. Using a stress-free material can ensure that the plate layer and suspension arrangement do not bend due to a stress gradient in the material in an equilibrium position.

As discussed above, the maximum allowable bimetallic bending of the plate wafer can be a limiting factor for the maximum acceleration of the movable plate provided by the electromagnetic actuator and, therefore, limit the speed of the micro mover. There are two components of plate bending. The first one is initial bending of the plate at a reference temperature, for example, at room temperature. The second one is related to an additional bending (or flattening) of the plate in the working temperature range. Improvement in micro mover bending performance can be achieved by thickening silicon in the areas of the movable plate that are disposed beneath metal, for example metal layer used to form coils, and thinning silicon in the areas of the movable plate that are not disposed beneath metal. Local thinning of the plate can be achieved using different etching techniques. For example, dry etching process can be used for thinning of the plate.

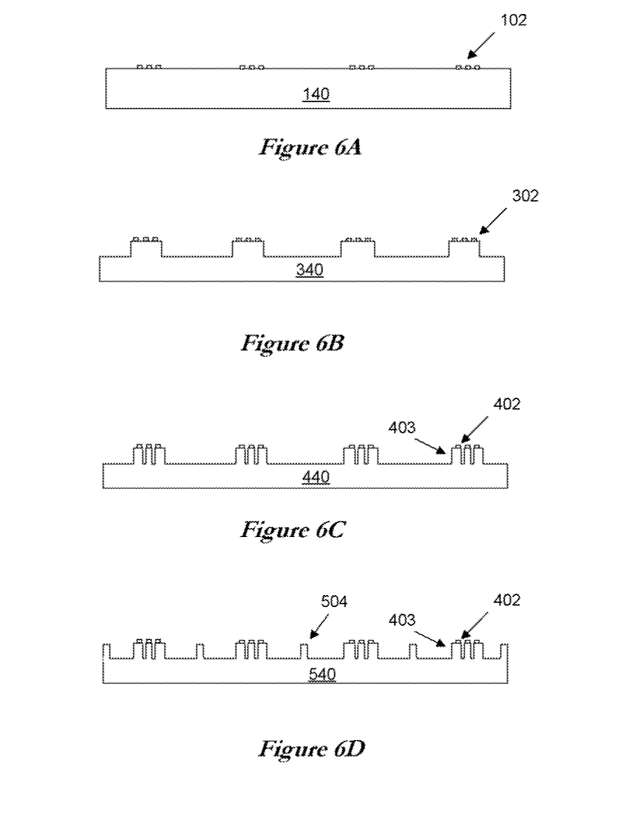

Some illustrative examples of movable plate cross-sections are shown in FIGS. 6A through 6D. FIG. 6A is a cross-section of a movable plate 140 having a uniform thickness. Coils 102 are disposed on the same surface of the movable plate 140. A thickness of the movable plate 120 is chosen having satisfactory bending characteristics. FIG. 6B is a cross-section of a movable plate 340 having areas around the coils 302 micro-machined. A thickness of the movable plate 340 disposed beneath the coil 302 is substantially the same as the movable plate 102 of FIG. 6A, though if desired the movable plate 340 can be somewhat thicker. Micro-machining reduces the mass of the movable plate 340 without substantially adversely affecting the bending characteristics of the movable plate 340. A minimum thickness of the movable plate 340 can be determined based on bending tolerances and wafer processing capabilities.

Referring to FIG. 6C, a cross-section of a movable plate 440 is shown wherein trenches 403 are etched between turns of the coils 402 in addition to areas around the coils 402. A further decrease of mass of the movable plate 440 can be achieved without substantially adversely affecting the bending characteristics of the movable plate 440. FIG. 6D is a cross-section of a movable plate 540 having stiffeners 504 micro-machined from the movable plate 540. The stiffeners can decrease bending of the movable plate 540 and allow further thinning of the movable plate 540, thereby enabling further reductions in the mass of the movable plate 540. The smaller mass can increase maximum acceleration of the movable plate 540 (using an equivalent actuator), or the smaller mass can reduce the maximum force provided by the equivalent actuator and its power consumption.

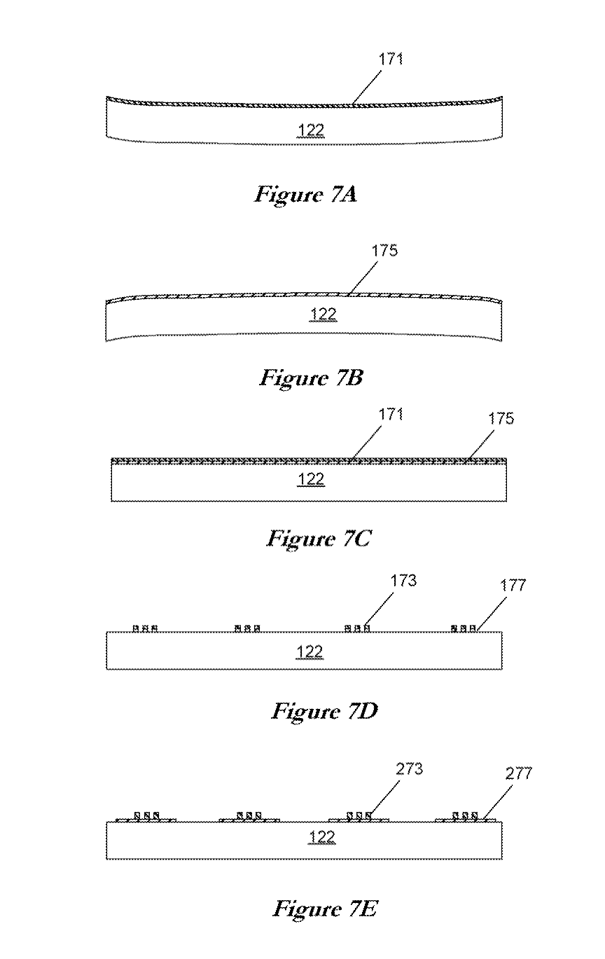

In still further embodiments, bimetallic bending of the movable plate can be reduced by employing a film stack in which thermo-mechanical stress is partially or mostly compensated due to selection of materials having different thermal expansion coefficients (TCE) and deposition conditions. FIG. 7A illustrates a silicon plate wafer 122 having a metal layer 171 (e.g. copper or some other highly conductive material) deposited at elevated temperature. Assuming that the metal material has a larger TCE than silicon, the plate wafer 122 at room temperature tends to bend such that the exposed surface of the metal layer 171 is concave in shape. FIG. 7B illustrates a silicon plate wafer 122 having a thermally grown silicon dioxide layer 175 (i.e. thermal oxide). As thermally grown silicon dioxide has a lower TCE than silicon, and it is grown at elevated temperature (typically 900-1200° C.) the plate wafer 122 tends to bend such that the exposed thermal oxide surface is convex in shape. FIG. 7C illustrates a silicon plate wafer 122 having a thermal oxide layer 175 deposited over silicon, and a metal layer 171 deposited over the thermal oxide layer 175. Where the bending characteristics of the plate wafer 122 having metal and thermal oxide, respectively, deposited over the silicon are taking into account, the metal layer 171 and thermal oxide layers 175 can urge bending in competing directions, thereby reducing the overall bending of the plate wafer 122 comprising only one of the two layers disposed over silicon. By choosing the proper ratio of material thickness and deposition parameters it is possible to compensate initial bending of the movable plate 122 and significantly decrease bending in an operating temperature range.

Patterning of materials deposited on the movable plate allows further decrease of plate wafer bending. FIG. 7D illustrates a movable plate 122 having metal 173 deposited thereon to form coils. Thermal oxide 177 is left under the coil metal 173 and removed from the remaining part of the surface, exposing the silicon. Bending of the movable plate 122 is reduced by the minimization of material that can cause bending of the movable plate 122. In some cases, especially when a thick metal layer is needed for coils, required thickness of thermal oxide arranged only under metal features may be too high and, therefore, not practical (thermal oxide thicker than 1.0-1.5 μm requires a long oxidation process). Referring to FIG. 7E, thermal oxide 277 can be disposed under metal features 273, and further over other surface of the movable plate 122. Selecting a proper pattern of the area having thermal oxide formed thereon can allow compensation of bending while the thermal oxide layer is kept relatively thin (preferably, below 1.5 μm).

In other embodiments, materials other than thermal oxide can be used for compensation of movable plate bending due to metal features. For example, such materials can include plasma enhanced chemical vapor deposition (PECVD) silicon dioxide, PECVD silicon nitride, low pressure CVD (LPCVD) silicon nitride, and LPCVD silicon oxy-nitride. A compensation layer can be deposited at an elevated temperature, and the TCE of the material used as a compensation layer can be smaller than the TCE of silicon in the temperature range between the deposition temperature and room temperature. In still other embodiments, multiple different compensation layers can be employed to compensate for movable plate bending caused by metal features.

In some embodiments, one or more compensation layers can be deposited on the opposite (with respect to the coils) side of the movable plate. This option can enable flexibility both in the microstructure design and in the process design. To compensate for bimetallic bending of the plate due to presence of the coils the compensation layer on the opposite side of the plate can be deposited at an elevated temperature, and the TCE of the material used as a compensation layer can be larger than a TCE of silicon in the temperature range between the deposition temperature and room temperature.

The flatness of a movable plate can vary over a range of operating temperature. For example, if coils comprising copper are disposed on the back side of a movable plate comprising silicon, the differential thermal expansion between the silicon movable plate and the copper coils can cause the movable plate to bend out of plane, potentially beyond a required flatness tolerance (e.g. 1 μm). To reduce the out of plane bending, an SOI structure can be employed having a thermally grown oxide layer buried within a stack forming part of a media stage. The coils can be formed over a thin LPCVD oxide layer. Subsequently, the wafer is thinned until the buried oxide layer is exposed. The thermally grown oxide deposited at an elevated temperature will tend to cause the media stage to bend in a first direction such that the surface of the movable plate has concave shape. However, since the copper coils can be deposited on the opposite side of the stack at a temperature, which can be close to room temperature, the differential bending caused by the coils causes the movable plate to bend in a second, opposite direction. The net result is that the flatness of the movable plate remains within tolerances over a desired temperature range.

In general, structures comprising a metal deposited at a low temperature (e.g. electroplated metal) can be more difficult for compensation of bending of the movable plate due to small initial bimetallic bending of the movable plate combined with the large temperature dependence of the bending due to a difference in TCE between metal and silicon. The compensation layer(s) should have approximately the same bending characteristics, but opposite signs of temperature dependence. Deposition of compensating layers on both sides of the movable plate can be used for compensating of bending induced by a coil metal deposited at low temperature.

The stiffness of the suspension arrangement can determine the required maximum actuator force for a required range of movable plate displacement and for a required maximum acceleration. Preferably, the suspension arrangement is formed using deep reactive ion etching (deep RIE)—a process that allows forming profiles with near vertical walls. Deviation of suspension flexure side walls from verticality can affect the stiffness of the suspension arrangement. The larger the required etching depth, the thicker the suspension flexure should be in order to maintain small relative variation of suspension stiffness. It is desirable to have an aspect ratio of the suspension flexures below 25:1 and, preferably, below 10:1 to ensure good reproducibility of suspension flexure profile and suspension stiffness. The stiffness of a suspension flexure is proportional to the cube of its thickness in the direction of bending, and directly proportional to the width of the flexure. Therefore, maintaining the same aspect ratio for suspension flexures can cause increased stiffness of the suspension arrangement for lateral bending proportional to the fourth power of movable plate thickness. Correspondingly, both required actuator force and actuator power consumption rapidly increase with increase of plate thickness.

Preferably, thinning of the plate wafer is done after bonding of the plate wafer to the cap wafer. This option allows avoiding processing and handling of thin wafers. Different bonding patterns can be used in different applications. However, it is highly desirable to minimize the area occupied by the bonding layer because it may cause built-in stress and bending of the wafer stack, which later will be transferred into thickness non-uniformity and initial bending of the movable plate and suspension arrangement. Thinning of the bonded stack of the plate wafer and the cap wafer can be performed using standard grinding and/or polishing steps (e.g. chemical-mechanical polishing (CMP)).

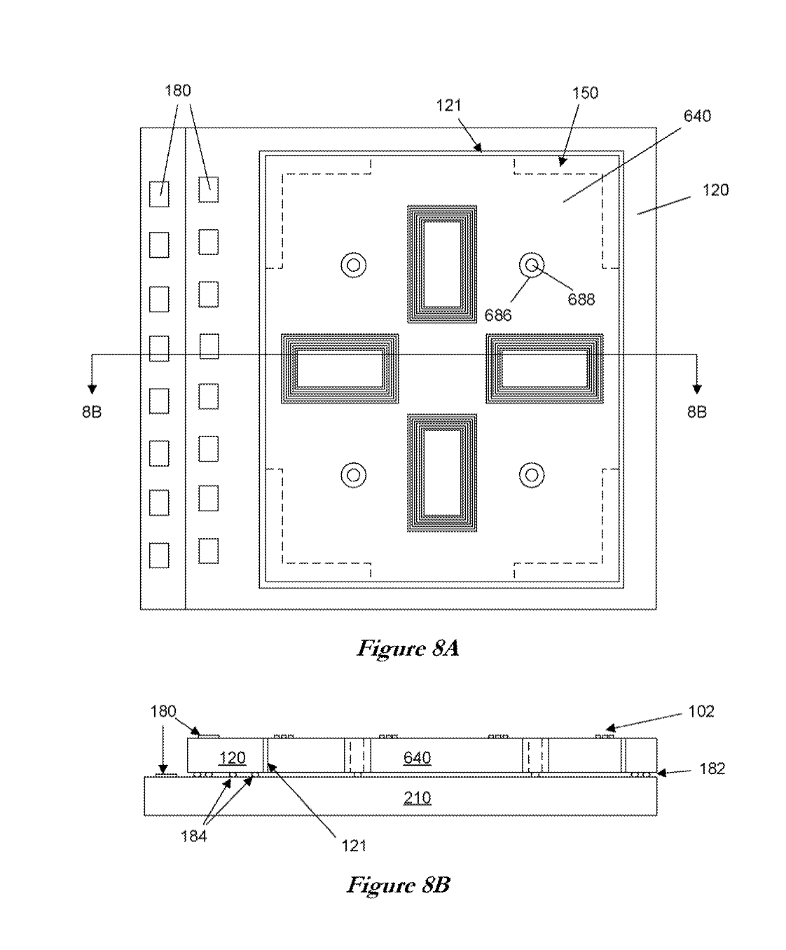

In some applications, the flatness of the plate layer is more relevant. For example, fabrication of some probe storage devices can require a nanoimprinting step, which, in turn, can require a very high flatness of the plate layer. However, the plate wafer is bonded to the cap wafer only in some areas (bond rings). Therefore, when the stack of plate and cap wafers is loaded with some force during wafer thinning steps this load causes vertical deflection of unsupported areas in the plate wafer. As a result, flatness of the plate layer achieved after wafer thinning can be compromised. Flatness of the plate layer after thinning can be improved by using some number of supports for the movable plate as shown in FIGS. 8A and 8B. Supports 688 under the movable plate 640 are created by bonding the plate wafer in the plate area 640 to the cap wafer 210 at the wafer bonding step. It is known that the maximum deflection of a diaphragm under a uniformly distributed load is proportional to the fourth power of diaphragm linear dimension (i.e. radius of circular plate or side length of square plate). Therefore, using several supports 688 beneath the movable plate 640 can significantly decrease parasitic bending of the plate wafer during thinning, decreasing plate layer shape distortion.

Supports 688 should be disconnected with the movable plate 640 in order to allow motion of the movable plate 640. This can be done at the same time that the suspension arrangement 150 is defined by etching through the plate wafer. Posts 687 shown in FIGS. 8A and 8B can be formed by etching a gap 686 around the posts 687 bonded to the cap wafer 210. The posts 687 can be used as stops for the movable plate 640, increasing a level of protection of the suspension arrangement 150 against shocks. The maximum motion of the movable plate 640 can be limited by the width of the gap 686 between the movable plate 640 and the post 687. Preferably, the gap 686 has a shape that allows contact between the movable plate 640 and the post 687 only along a small surface area. This is important to avoid sticking between the movable plate 640 and the post 687.

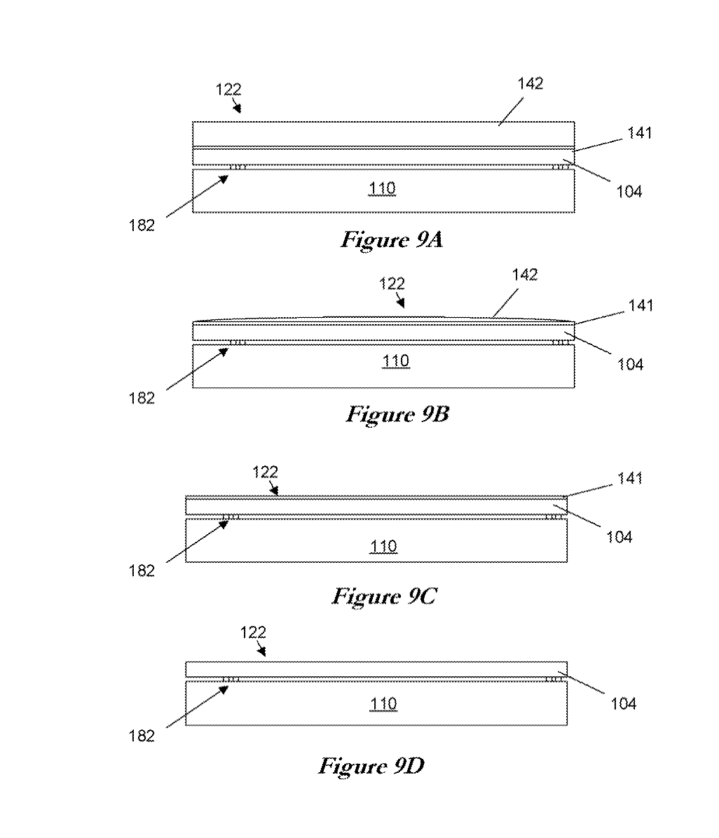

Besides getting low bending of the movable plate, as it was discussed above, using SOI wafers as initial material for the plate wafers can be beneficial for achieving both uniform thickness of the plate layer and very high quality surface of the plate. FIG. 9A illustrates a plate wafer comprising an SOI wafer. The plate layer 104 can be formed by bonding the plate wafer 122 and a cap wafer 110, and thinning the bonded stack. After thinning, a thickness of one or more underlying SOI layers can correspond to the target movable plate thickness. Referring to FIG. 9B, a top layer 142 of the SOI plate wafer 122 comprising silicon is thinned, for example using grinding followed by polishing. Thinning of the plate wafer 122 can be stopped before, or soon after exposing a buried oxide layer 141 disposed beneath the silicon layer 142. As can be seen, after thinning of the plate wafer 122, the thickness of the plate wafer 122 is non-uniform. This non-uniformity can be a result of diaphragm deflection during wafer thinning. The wafer stack can be subjected to a silicon etching process having high selectivity to silicon dioxide. The remaining silicon 142 above the buried oxide layer 141 can be removed at this step (as shown in FIG. 9C). The flatness of the plate wafer 122 after silicon etching step can be determined by the flatness of the interface between the layers in the SOI stack, which is typically exceptionally good, and a flatness of the bonded stack of the cap wafer 110 and the plate wafer 140. The surface quality of the top surface of the plate wafer 122 after thinning can be determined by the surface quality of the buried oxide layer 141.

During etching of silicon 142, the buried layer 141 of silicon oxide will be exposed non-uniformly. Both some non-flatness of the wafer stack and some surface roughness after silicon etching step can be related to difference in silicon dioxide etching time in different areas. In order to eliminate this source of non-flatness and roughness it is possible to strip off silicon dioxide as well (as shown in FIG. 9D). The silicon dioxide can be wet etched, for example, using hydrofluoric acid (HF) or buffered oxide etch (BOE). Both etching solutions remove silicon dioxide without substantially attacking underlying silicon.

As described above, the micro-mover can be subjected to mechanical shock and/or vibrations. A thin layer of air between the cap(s) and the movable plate provides squeeze film damping of out-of-plane motion of the movable plate. It can be desirable to maintain a small air gap between the movable plate and one or both caps to achieve a desirable effect of squeeze film damping. In an embodiment, a height of the air gap between the cap and the plate is in the range of 1-30 μm. In some areas of the stack, an air gap can be taller to allow some out-of-plane motion of the movable plate and/or the suspension arrangement while avoiding mechanical contact with one or both of the cap wafers. Further, as mentioned above, small area stops can be formed either on the movable plate or in the recess on the cap wafer in order to allow mechanical contact between the plate and the cap wafer for shock protection.

In some embodiment, it can be desirable to include wide gaps around the suspension flexures to protect the suspension arrangement during shock events. Free motion of long and compliant L-shaped flexures shown in FIGS. 5A and 5B does not create a significant stress in the suspension and allows advanced protection of the structure during shock events. Such features can help protect the movable plate during several steps in the fabrication process after the movable plate is released and before the movable plate is bonded either with the second cap or with a temporary carrier.

In order to provide control of the motion of the movable plate it can be beneficial to maintain the main resonance frequency of the movable plate within a desired range. The resonance frequency is proportional to the square root of the ratio of suspension spring constant and mass of the movable plate. Therefore, the main resonance frequency can be controlled by changing either spring constant of suspension or by changing mass of the movable plate.

In some cases mass of the movable plate can be decreased by micromachining the movable plate from the coil side, as described above in reference to FIGS. 6B-6D. In particular the plate can be thinned in the areas inside the coils, between the teeth of capacitors (used for position sensing as it is described in the next section), and between the coils and capacitors. Some adjustments in thickness of dielectric layers used for compensation of bending of the movable plate might be necessary in case of micromachining of the movement plate to maintain advantageous bending characteristics. Decrease of the mass of the movable plate allows an increase in the main resonance frequency of the movable plate, and improves shock protection while decreasing vibration sensitivity of the movable plate because the inertial force acting on the movable plate is proportional to the mass of the movable plate.

Position Sensing

A position of the movable plate relative to a cap wafer and/or the stationary portion can be determined using position sensors. Myriad different techniques for determining position can be employed, including use of capacitive sensors, Hall-effect sensors, and temperature sensors.

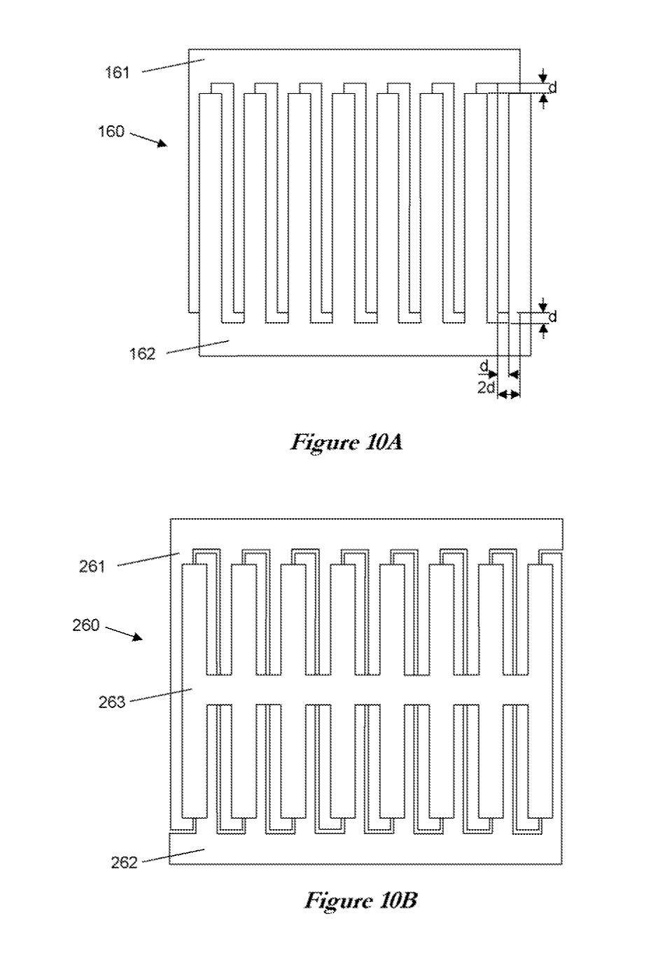

Capacitive sensors for use in determining a position of a movable plate can comprise an electrode fixedly connected or integrally formed with the movable plate and an electrode fixedly connected or integrally formed with one of the top cap and the bottom cap. The electrodes of the capacitors should be shaped to provide a change in capacitance due to a motion of the movable plate in at least one direction. Referring to FIG. 10A, a single-axis capacitive sensor 160 is shown comprising a stationary electrode 161 adapted to be connected with the cap and a movable electrode 162 adapted to be connected with the movable plate. The capacitive sensor 160 can detect horizontal motion of the movable plate in the X-axis of the plane of the page. The capacitive sensor 160 can further detect a change in vertical separation between the stationary electrode 161 and the movable electrode 162 along the Z-axis disposed perpendicular to the plane of the page, vertical motion of the movable plate in the Y-axis of the plane of the page, and rotation of the movable electrode 162 with respect to the stationary electrode 161.

With no out-of-plane motion (e.g. rocking motion) of the movable plate, there are four independent variables defining mutual position of the electrodes: X and Y displacement within the Cartesian plane, Z separation and an angle of rotation within the Cartesian plane. Four position sensors can be used to measure the values of the four independent variables. However, the movable plate can exhibit out-of-plane motion, such as rocking or shocks. In such circumstances, opposite edges of the movable plate may have different Z-displacement as a result of the out-of-plane motion. At least two additional position sensors can be implemented to obtain information about rocking motion of the plate. One of the sensors can be used for evaluation of rocking motion in X-Z plane and another sensor can be used for evaluation of rocking motion in Y-Z plane. At least six sensors can be used in such an implementation.

Referring to FIG. 10B, in some embodiments, a micro-mover can comprise a pair of capacitive sensors positioned at four locations using each pair of capacitive sensors for extracting a ratiometric signal independent of Z-displacement of the movable plate. Two electrodes 261, 262 are formed on one or both of the top and bottom caps. A third electrode 263 is integrally formed or fixedly connected with the movable plate to form a differential pair. Two capacitors are formed between the first electrode 261 and third electrode 263, and between the second electrode 262 and the third electrode 263. A ratio of capacitances can be sensitive to horizontal displacement of the movable plate with respect to the stationary portion in the plane of the figure (X-displacement) and this ratio can be insensitive to Y and Z displacements of the movable plate with respect to the stationary portion.

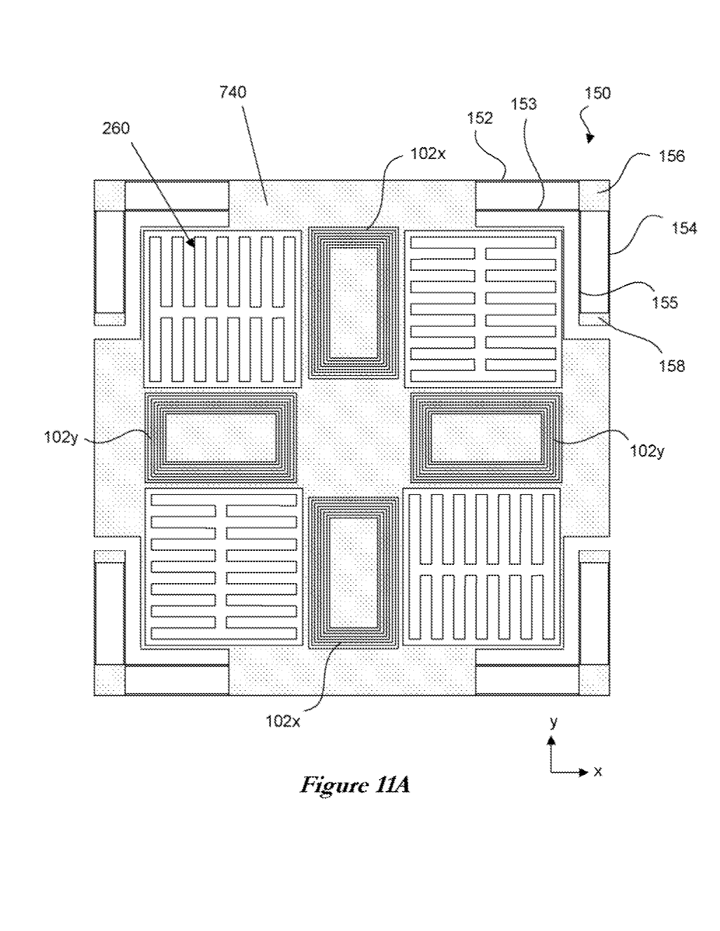

Referring to FIG. 11A, a movable plate 740 is shown having four electrodes 260 integrally formed or fixedly connected with the movable plate 740. As exemplified, the electrodes 260 are arranged in each quarter of the movable plate 740. Two electrodes are designed to provide signals proportional to X displacement of the movable plate 740, and two other electrodes are designed to provide signals proportional to Y displacement of the movable plate 740. Preferably, each electrode 260 on the movable plate faces a differential pair of electrodes on one or both of the caps (not shown). Processing signals from all capacitive sensors allows extracting three displacement and three rotational components of the motion of the movable plate 740 with respect to one or both caps.

In alternative embodiments, micro-mover can have larger number of capacitive sensors. In particular, pairs of capacitive sensors sensitive to the same type of motion (lateral (X), transverse (Y), X-Y skew or others) can be implemented in such a way that output signal of the first sensor is close to zero level and the output signal of the second sensor is close to its full scale output when the movable plate is in equilibrium position. When the movable plate is in an extreme position then output signal of the first sensor is close to its full scale output and the output signal of the second sensor is close to zero.

In alternative embodiments, Hall-effect sensors sensitive to magnetic field can be used to determine the position of the movable plate. Hall-effect sensors measure position based on changes of the mobility of carriers in the presence of magnetic field. Hall-effect sensors can be employed in a micro mover, for example, in the form of magneto-resistors or magneto-transistors. Hall-effect sensors can be arranged in areas of the movable platform where a component of the magnetic field has its largest gradient. Areas with large gradients of magnetic field exist in the middle of the coils where the magnetic field changes polarity. Displacement of the movable plate causes changes in the magnetic field created by stationary magnets and can be detected by the Hall-effect sensors.

In still further embodiments, thermal position sensors can be used to determine the position of the movable plate. Myriad different types of thermal sensors can be employed. For example, a thermal position sensor containing a heater and a differential pair of temperature sensors can be employed. In one embodiment, a stationary heater (e.g. a resistive heater) can be formed on one of the cap wafers, and two temperature sensors can be connected with the movable plate and located symmetrically with respect to the heater so that in a neutral position a differential signal from the pair of temperature sensors is small. When the movable plate is urged away from a neutral position the distance between the stationary heater and one of the temperature sensors increases. Correspondingly, the distance between the heater and the other of the temperature sensors decreases. The temperature difference resulting from this movement causes an electrical signal proportional to the displacement of the movable plate.

Similarly to capacitive position sensors at least four magnetic or temperature sensors can be employed in order to measure displacement of the movable plate within the Cartesian plane and the angle of rotation of the movable plate within the Cartesian plane. At least two additional sensors can be employed in order to measure rotation of the movable plate in X-Z and Y-Z planes.

Electrical connections to the movable plate may require use of bridges. It is desirable to minify the use of bridges; therefore, it can be advantageous to employ position sensors requiring the smallest number of electrical connections between the movable plate and the stationary portion. Capacitive sensing allows electrodes located on the movable plate to be connected with the substrate, which can act as a common electrode. The substrate potential can be set to ground or to the high potential. Connecting capacitor plates to the substrate creates parasitic capacitors between the substrate and the stationary portions. In order to reduce the parasitic capacitance the movable plate can be micro-machined between the fingers of the electrodes. Shallow cavities in the areas between the fingers can reduce parasitic capacitance.

Another approach illustrated in FIG. 11B shows arrangement for capacitive sensors for position sensing. Capacitors C1 and C2 are connected in series. One plate of the capacitor C1 is located on the stationary portion and the other plate is located on the movable plate. Similarly, one plate of the capacitor C2 is located on the stationary portion and the other plate is located on the movable plate. Plates of capacitors C1 and C2 located on the movable plate are connected to each other. Capacitors C1 and C2 are connected through terminals A and B to other components of the sensing and signal conditioning circuit. As it can be seen, there is no need for an external connection to the plates of capacitors C1 and C2 located on the movable plate due to capacitive coupling between the plates of capacitors C1 and C2 located on the movable plate and plates located on the stationary portion. Therefore, the described arrangement eliminates a necessity of electrical connections of the capacitors located on the movable plate with the stationary portion and reduces number of required electrical connections between the movable plate and the stationary portion.

Hall-effect and temperature sensors require at least two independent connections per sensor. Further, temperature sensors utilizing heat transfer through the air between the heater and the sensors may be less accurate than Hall-effect sensors and capacitive sensors. Resolution provided by Hall-effect sensors and capacitive sensors is expected to be better than that of thermal sensors. Still further, capacitive sensors have certain advantage related to low power consumption in comparison with the magnetic and temperature sensors.

Fabrication of a Micro-Mover Having One Cap

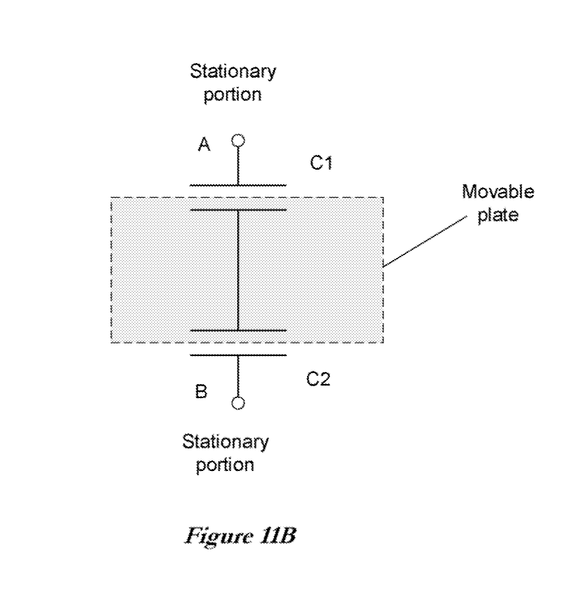

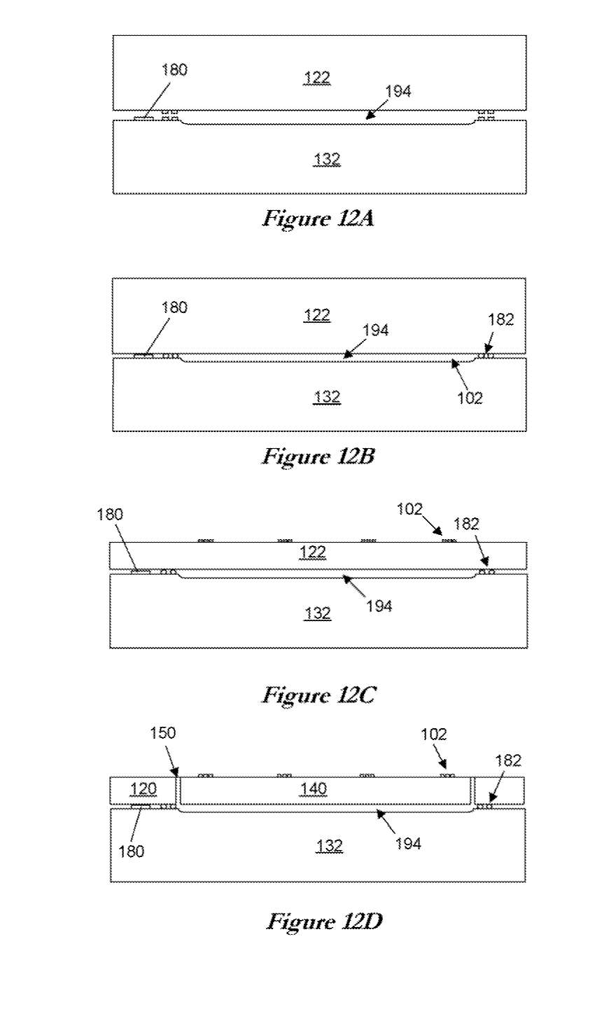

Referring to FIGS. 12A through 12D an embodiment of a method of forming a micro-mover having a single cap is shown. FIG. 12A shows pre-processed cap wafer 132 and plate wafer 122 before bonding. Pre-processing of the cap wafer 132 and plate wafer 122 can be achieved by standard semiconductor processing operations that are well known in the art. The pre-processed cap wafer 132 has a recess 194 and a bonding pattern 182. Optionally, the cap wafer can have components of position sensors (not shown). For example, capacitor plates can be formed in the recess 194 and connected to the pads 180. Pre-processed plate wafer has a bonding pattern 182. Plate wafer also can have components of the position sensors. For example, capacitor plates can be formed on the principle surface 108 of the plate wafer 122 facing the cap 132.

FIG. 12B shows cap wafer and plate wafer bonded together. The bonding between the wafers can be liquid-proof and, preferably, hermetic. Metal lines located on the principle surface 108 of the plate wafer 122 facing the cap 132 can be transferred to the cap wafer as a result of bonding and connected to the bond pads 180. Referring to FIG. 12C, plate wafer 122 can be thinned to a required remaining thickness after bonding to the cap wafer 132. Preferably, thinning is done by grinding followed by a polishing step for providing improving uniformity of the plate surface. The polishing step can be performed using one of mechanical polishing and CMP, or a combination of mechanical polishing and CMP. Further, coil 102 can be formed on the principle surface 106 of the plate wafer 122. Coil can be connected to the bond pads 180.

Referring to FIG. 12D, the suspension arrangement 150 can be defined, and the movable plate 140 can be released, by way of etch processing, for example by RIE. Highly anisotropic RIE processing can enable the formation of suspension flexures with substantially uniform widths and large aspect ratio (thickness to width). Such suspension flexures have high vertical stiffness, and are much more compliant in the Cartesian plane. Pad expose cuts providing access to bond pads XXX located on the cap wafer 132 can be etched through the plate wafer 122 at the same step.

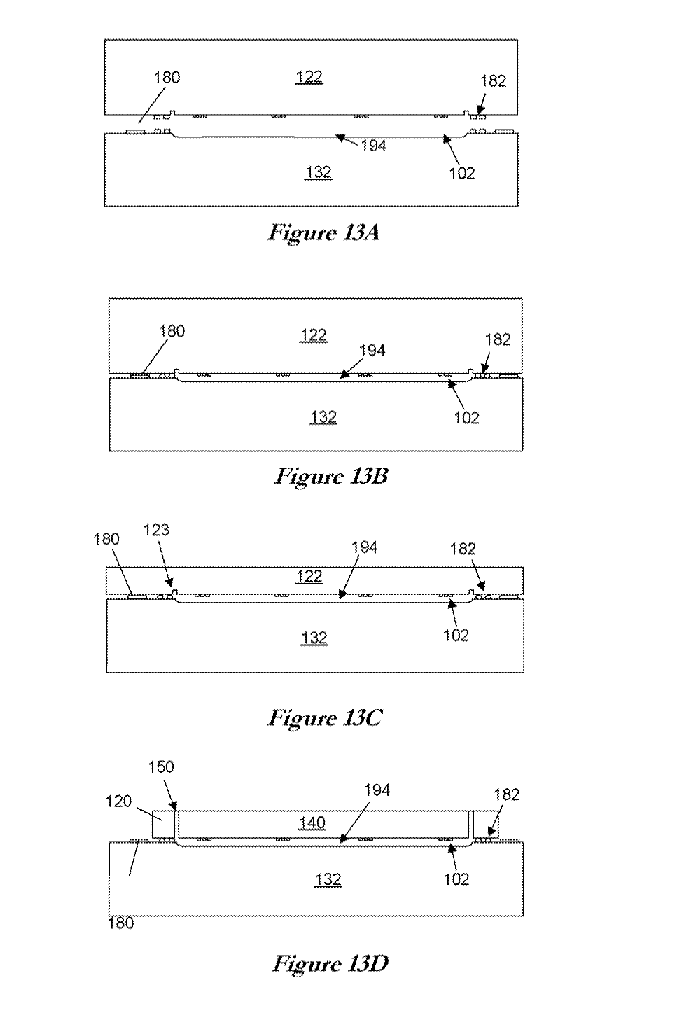

FIGS. 13A through 13D illustrate another embodiment of a method of forming a micro-mover having a single cap. FIG. 13A shows pre-processed cap wafer 132 and plate wafer 122 before bonding. Pre-processing of the cap and plate wafers 132, 122 can be achieved by standard semiconductor processing operations that are well known in the art. The pre-processed cap wafer 132 has a recess 194 and a bonding pattern 182. Optionally, the cap wafer 132 can have components of position sensors (not shown) formed in the recess 194 and connected to the pads 180. Pre-processed plate wafer has bonding pattern 182 and a coil 102 formed on the principle surface 108 of the plate wafer. Both coil and components of position sensors can be connected to the bond pads 180 located on the cap wafer 132 by transferring metal lines from the plate wafer 122 to the cap wafer 132 at the wafer bonding step. Plate wafer 122 also can have components of the position sensors. For example, capacitor plates can be formed on the principle surface 108 of the plate wafer 122 facing the cap 132. Plate wafer 122 also can have micromachined grooves 123 that can define shape of the suspension and bridges transferring metal lines from the movable plate to the stationary portion after release etch.

FIG. 13B shows cap wafer and plate wafer bonded together. The bonding between the wafers can be liquid-proof and, preferably, hermetic. Plate wafer 122 can be thinned to a required remaining thickness at the next step, as it is shown in FIG. 13C. Preferably, thinning is done by grinding followed by a polishing step for providing improving uniformity of the plate surface. The polishing step can be performed using one of mechanical polishing and CMP, or a combination of mechanical polishing and CMP.

Referring to FIG. 13D, the suspension arrangement 150 can be defined, and the movable plate 140 can be released, by way of etch processing, for example by RIE. Highly anisotropic RIE processing can enable the formation of suspension flexures with substantially uniform widths and large aspect ratio (thickness to width). Such suspension flexures have high vertical stiffness, and are much more compliant in the Cartesian plane. Pad expose cuts providing access to bond pads XXX located on the cap wafer can be etched through the plate wafer 122 at the same step.

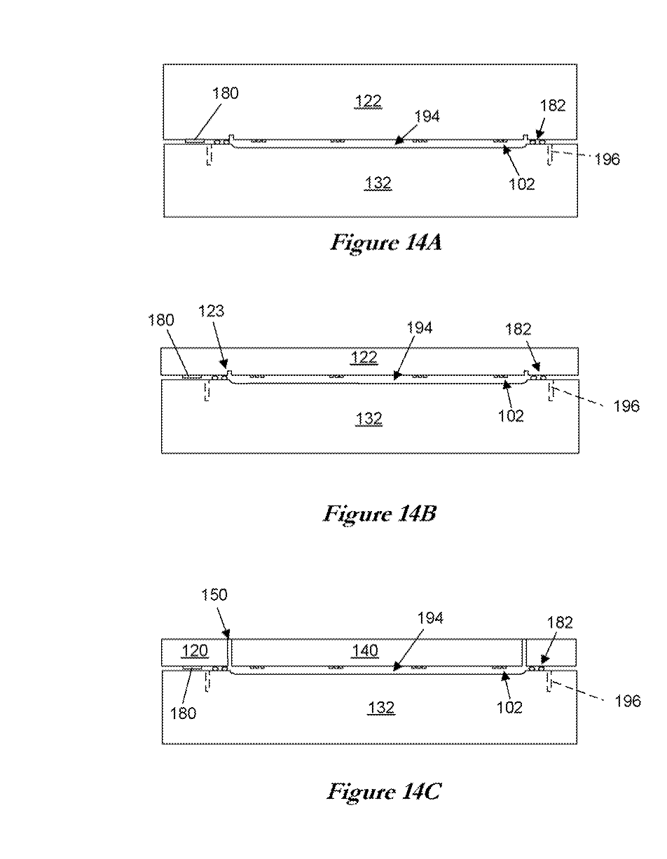

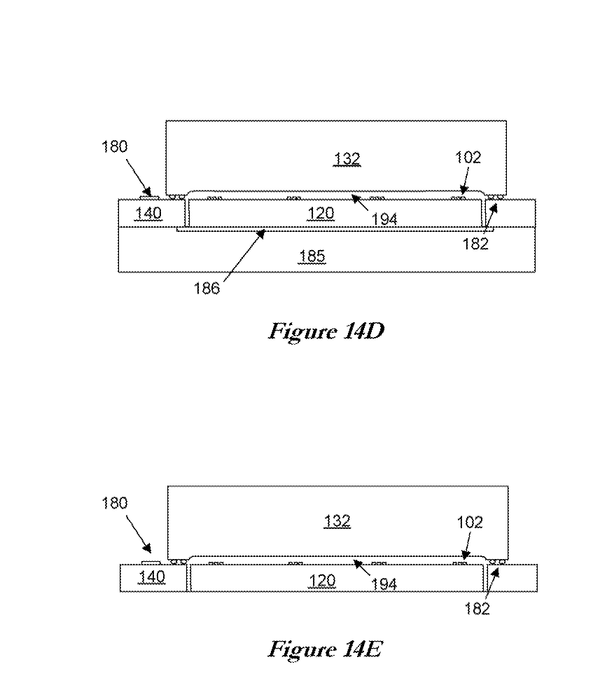

Referring to FIGS. 14A through 14E, still another embodiment of a method of forming a micro-mover having a single cap wafer is shown. Pre-processing of the cap wafer 132 and plate wafer 122 can be achieved by standard semiconductor processing, for example using myriad different deposition, lithography, and etch process techniques that are well known in the art. The pre-processed plate wafer 122 has a bonding pattern 182 and a coil 102 formed on the principle surface 108 of the plate wafer and connected to the bond pads 180. Plate wafer 122 also can have components of the position sensors. For example, capacitor plates can be formed on the principle surface 108 of the plate wafer 122 facing the cap 132. Plate wafer 122 also can have micromachined grooves 123 defining suspension and bridges transferring metal lines from the movable plate 140 to the stationary portion 120 after release etch. The pre-processed cap wafer 132 has a recess 194 and a bonding pattern 182. Optionally, the cap wafer can have components of position sensors (not shown) formed in the recess 194. The pre-processed cap wafer 132 and plate wafer 122 are bonded together to provide liquid-proof sealing and, preferably, hermetic sealing 182 of the cavities 194 around the movable plate 140 within the stack. Metal lines formed on the cap wafer can be transferred to the plate wafer 122 and connected to the pads 180 as a result of the bonding step.

Referring to FIG. 14B, the plate wafer 122 can then be thinned to a required remaining thickness. Preferably, thinning is done by grinding followed by a polishing step for providing improving uniformity of the plate surface. The polishing step can be performed using one of mechanical polishing and CMP, or a combination of mechanical polishing and CMP.

Referring to FIG. 14C, the suspension arrangement 150 can be defined, and the movable plate 140 can be released, by way of etch processing, for example by RIE. Highly anisotropic RIE processing can enable the formation of suspension flexures with substantially uniform widths and large aspect ratio (thickness to width). Such suspension flexures have high vertical stiffness, and are much more compliant in the Cartesian plane. Optionally, cuts can be etched along dicing lines 123 through the plate wafer 140.

Cuts 196 through the cap wafer 132 should be formed to remove portions of the cap wafer 132 and provide access to the bond pads 180 formed on the stationary portion 120. After release etching the microstructure can be fragile; therefore, the wafer stack can be mounted on a temporary carrier 185, as shown in FIG. 14D. The temporary carrier 185 can comprise a silicon or plastic wafer or some material having comparable qualities, as well as a thermal release tape. The temporary carrier 185 should have good adhesion to the stationary portion 120 and frame of the wafer that is not occupied by dice while not adhesively contacting the released movable plate 140 and, preferably, not mechanically contacting the released movable plate 140. In order to achieve that the temporary carrier 185 can beneficially include a recess 186 under the movable plate 140, similar to the cavity 194 of the cap wafer 132. After mounting or connecting the wafer stack to the temporary carrier 185, the bond pads 180 on the stationary portion 120 can be exposed using sawing, laser cutting, RIE etching or other techniques that allow selective removal of the material above the bond pads. Dicing grooves 196 of the cap wafer 132 allows making pad expose cuts without damaging metal lines and bond pads 180 located under the cut area. After or while the bond pads 180 are exposed, dicing is performed. There are different options for depth of the cut at the dicing step. The cut can be performed through the wafer stack and the temporary carrier 185, or the cut can be performed through the wafer stack. Preferably, both pad 180 expose and dicing are done using sawing. The temporary carrier 185 can be removed after the dicing step. Alternatively, the temporary carrier 185 can be kept as a carrier for the micro mover and removed before packaging of the micro mover die.

In alternative embodiments, it can be desired that pad expose cuts and dicing be performed before release etching of the movable plate 140, thereby further resisting contamination and/or damage to the movable plate 140. In such embodiments, release etching is performed at chip level, rather than wafer level. However, with an appropriate carrier the micro-mover can be batch processed. Such methods can eliminate use of a temporary carrier.

Fabrication of a Micro-Mover For a Probe Storage Device

Probe storage devices enabling higher density data storage relative to current technology can include cantilevers with contact probe tips as components. Such probe storage devices typically use two parallel plates. A first plate (also referred to herein as a contact probe tip stage) includes cantilevers with contact probe tips extending therefrom for use as read-write heads and a second, complementary plate (also referred to herein as a media stage) includes a media device for storing data. Motion of the plates with respect to each other allows scanning of the media device by the contact probe tips and data transfer between the contact probe tips and the media device.

In some probe storage devices, for example utilizing phase change materials in a stack of the media device, both mechanical and electrical contact between the contact probe tips and the media device enables data transfer. In order to write data to the media device, current is passed through the contact probe tips and the phase change material to generate heat sufficient to cause a phase-change in some portion of the phase change material (said portion also referred to herein as a memory cell). Electrical resistance of the memory media can vary depending on the parameters of the write pulse, and therefore can represent data. Reading data from the memory media requires a circuit with an output sensitive to the resistance of the memory cell. An example of one such circuit is a resistive divider. Both mechanical and electrical contact between the contact probe tip and the media device can also enable data transfer where some other media device is used, for example memory media employing polarity-dependent memory.

The media device can include a continuous recording media, or alternatively the media device can be patterned to define discrete memory cells having dimensions as small as approximately 40 nm or less. A contact probe tip can access a portion of the surface of the media device, the portion being referred to herein as a tip scan area. The tip scan area can vary significantly and can depend on contact tip probe layout and/or media device layout. For purposes of example, the tip scan area can approximate a 100 μm×100 μm (10,000 μm²) portion of the surface media device. To enable the contact probe tip to access substantially the full range of the tip scan area, the contact probe tip stage can move within the tip scan area and the media stage can be fixed in position. Alternatively, the contact probe tip stage can be fixed, and the media stage can move within the range of the tip scan area. The moving stage moves in both lateral (X) and transverse (Y) motion to traverse the tip scan area. Alternatively, both the contact probe tip stage and the media stage can move in a single direction, with one stage moving along the X-axis and the other stage moving along the Y-axis.

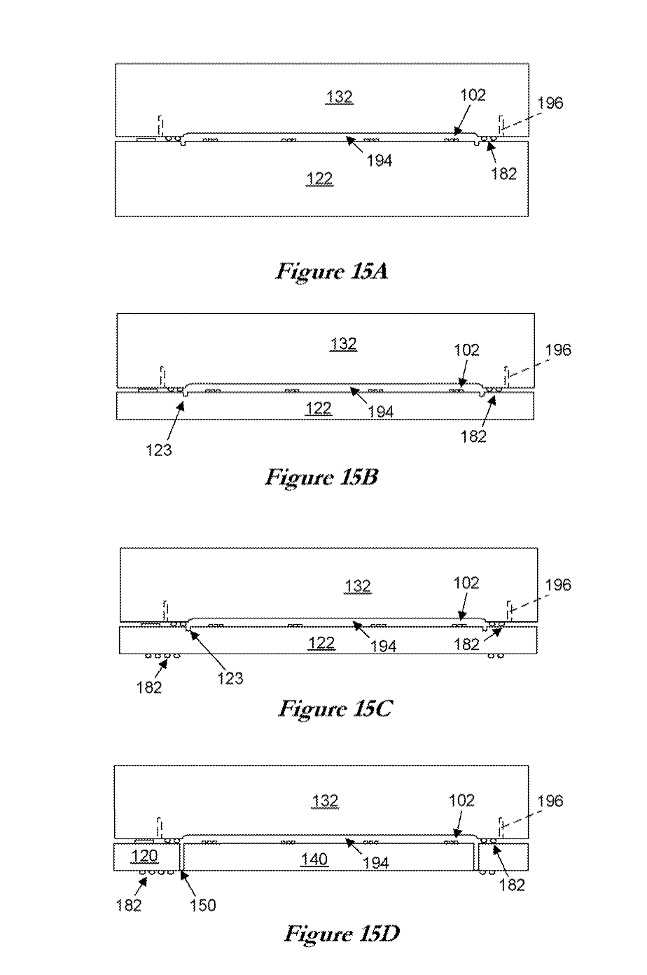

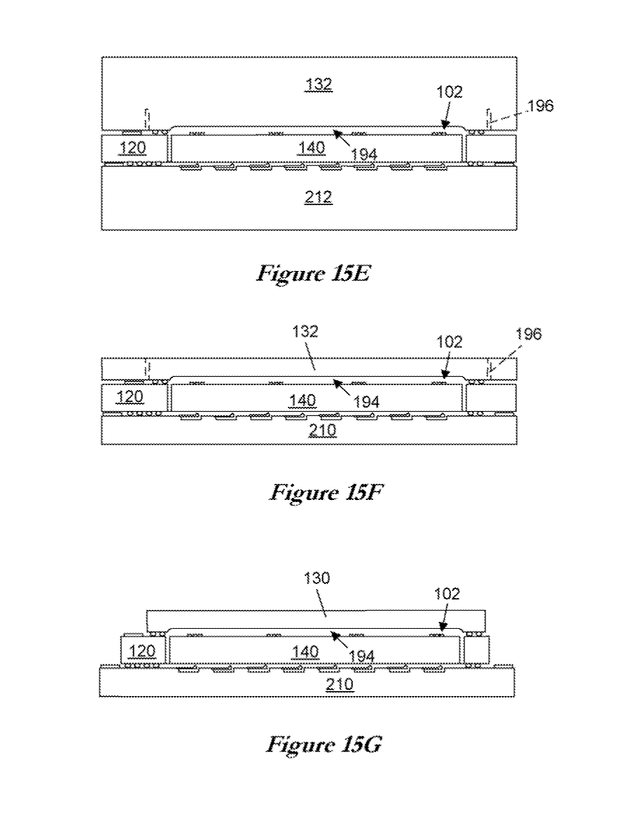

Referring to FIGS. 15A through 15G, an embodiment of a method of forming a micro-mover for use in moving a media stage relative of a probe storage device relative to a contact probe tip stage is shown. Pre-processing of the cap wafer 132 and plate wafer 122 can be achieved by standard semiconductor processing, for example using myriad different deposition, lithography, and etch process techniques that are well known in the art. The pre-processed cap wafer 132 and plate wafer 122 are bonded together to preferably provide hermetic sealing 182 of the cavities 194 around the movable plate 140 within the stack. The cap wafer 132 can include integrated circuits such as sensor circuits, amplifiers, multiplexers, memory, signal processing circuits, etc.

Referring to FIG. 15B, the plate wafer 122 can then be thinned to a required remaining thickness. Preferably, thinning is done by grinding followed by a polishing step for providing improving the uniformity of the plate surface. The polishing step can be performed using one of mechanical polishing and CMP, or a combination of mechanical polishing and CMP.

Referring to FIG. 15C, once the plate wafer 122 has been satisfactorily thinned, the wafer stack can undergo a plurality of deposition steps to form a media stack on the movable plate 140 (thereby forming a media stage), and a plurality of deposition, patterning and etch steps for forming a bonding pattern. The bonding pattern 182 can contain one or more closed contours around the movable plate 140. Preferably, the bonding material is electrically conductive and allows transferring of electrical lines from the stationary portion 120 to the tip wafer. Formation of a media stack on the movable plate 140 can include transferring patterns to define discrete cells for recording information and servo patterns. Referring to FIG. 15D, the suspension arrangement 150 can be defined, and the movable plate 140 can be released, by way of etch processing, for example by RIE. Highly anisotropic RIE processing can enable the formation of suspension flexures with substantially uniform widths and large aspect ratio (thickness to width). Such suspension flexures have high vertical stiffness, and are much more compliant in the X-Y plane. Optionally, cuts can be etched along dicing lines 123 through the plate wafer 140.

Referring to FIG. 15E, the plate wafer 140 can be bonded with the contact probe tip wafer 212. A bonding process can comprise myriad different techniques, as described above; however, the bonding process should include process parameters that do not undesirably alter the characteristics of the media stack. Further, the bonding process should not undesirably alter a stress gradient of the cantilevers connecting the contact probe tips with the contact probe tip wafer 212, or undesirably alter the bending characteristics of the movable plate 140. The gap between a surface of the media device of the movable plate 140 and the contact probe tip wafer can be hermetically sealed so that the movable plate 140 is disposed between the cap and the contact tip probe stage. Preferably the stationary portion 120 and/or the bond ring can have an approximately uniform height so that a sufficient gap is formed between the movable plate 140 and the contact probe tip wafer 110 and further so that a sufficient gap is formed between the coils and the cap 130.

In some embodiments, a lubricant can be formed on one or both of the media stack located on the movable plate and on the tips so that a restrictive frictional force between the array of tips and the movable plate 140 is sufficiently reduced.

Optionally, it can be desired that the contact probe tip wafer 212 be thinned to accommodate package specifications. For example, some standard packaging options for memory chips require memory chip thickness to be below 0.5-0.8 mm. Therefore, thinning of the stack of wafers may be appropriate for some memory applications. However, for systems in which probe storage devices replace hard disk drives, or other relatively bulky memory media, a memory chip need only be required to have a memory chip thickness below 2.0 mm. In such applications, it can be unnecessary to thin down the stack.

Where thinning of the contact probe tip wafer 212 is desired, preferably, thinning is performed prior to bonding of the contact probe tip wafer 212 with the plate wafer 140. A contact probe tip wafer 210 having undergone thinning by way of mechanical polishing, CMP polishing, and/or etch processing can have a thickness generally in a range of from 100-500 μm range. The contact probe tip wafer 210 provides a mounting surface during processing to thin the cap wafer 132, and during sawing steps; therefore, the contact probe tip wafer 210 should have a thickness sufficient to endure further processing. Thus, a thicker contact probe tip wafer 210 provides better stress relief to a wafer stack during wafer-level processing steps and to the micro mover structure after dicing.

Where thinning of the cap wafer 132 is desired, thinning can be preferably be performed subsequent to thinning of the contact probe tip wafer 210, as shown in FIG. 15F. A cap wafer 132 having undergone thinning by way of mechanical polishing, CMP polishing, and/or etch processing can have a thickness generally in a range of from 50-500 μm range. Thinning of both the contact probe tip wafer 212 and the cap wafer 132 can include a combination of thinning steps and/or techniques. For example, thinning can be started as grinding up to a certain wafer thickness followed by flash dry etching of the wafer surface. This combination allows achieving target wafer stack thickness without risk of damaging the movable structure due to deflection of diaphragms formed in the contact probe tip wafer and cap wafer above and below the movable plate.

Cuts through the cap wafer 132 should be formed to remove portions of the cap wafer 132 and provide access to the bond pads 180 formed on the stationary portion 120, and further to separate the wafer stack into die. Preferably, at least a portion of dicing grooves 196 of the cap wafer 132 is exposed during thinning of the cap wafer and the exposed pattern can assist in determining a correct position of the cuts at this step. After or while the bond pads 180 are exposed, dicing is performed. There are different options for depth of the cut at the dicing step. Preferably, both pad expose and dicing are done using sawing. The micro-mover after pad-expose cuts and dicing is shown in FIG. 15G.

When the stage stack 100 is assembled and, if necessary, thinned, at least one permanent magnet can generally be aligned with the coils 102 and a ferromagnetic shell enclosing the die. The combination of at least one permanent magnet and a ferromagnetic shell creates a required distribution of magnetic field in the gap between them, where the die is located and, therefore, enables electromagnetic actuation. For example, the permanent magnet can be located under the tip wafer 212 and the ferromagnetic shell can include a steel plate located above the top cap 130. In other embodiments, some other metals or alloys can be employed.

In contrast with a micro mover having one cap, the micro mover structure with two caps provides much better protection of the movable plate and does not require mounting on a temporary carrier. In the example given above, the contact probe tip wafer can be considered a substitute for a cap, while providing mechanical and environmental protection during processing as would a cap. However, a temporary carrier can be employed to increase mechanical strength of the stack and decrease yield loss due to handling and processing of thinned stacks of wafers.

The foregoing description of the present invention have been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A system for positioning a movable plate within a sealed environment, the system comprising:
a movable plate arranged in a plane;
a stationary portion arranged in the plane;
a suspension connected between the movable plate and the stationary portion;
a first cap fixedly connected with the stationary portion so that a cavity is disposed between the first cap and the movable plate;
a current path fixedly connected with the movable plate and disposed at least partially within the cavity;
a second cap fixedly connected with the stationary portion so that the movable plate is disposed between the first cap and the second cap;
a magnetic field device including:
a first plate,
a magnet associated with the first plate, and
a second plate;
wherein the first plate and the magnet are connected with the first cap so that the first cap is disposed between the magnet and the movable plate;
wherein the second plate is connected with the second cap so that the second cap is disposed between the second plate and the movable plate;
wherein the second plate, the first plate and the magnet are generally aligned so that a magnetic flux generated by the magnet is substantially contained between the first plate and the second plate; and
wherein the movable plate can be moved within the plane relative to the stationary portion when a current is applied to the current path.

2. The system of claim 1, further comprising:
a conductive bridge disposed between the stationary portion and the movable plate, the conductive bridge allowing electrical communication between the stationary portion and the movable plate.

3. The system of claim 2, wherein:
the suspension includes a plurality of flexures disposed between the movable plate and the stationary portion; and
the conductive bridge includes one or more metal lines disposed over the plurality of flexures.

4. The system of claim 2, wherein:
the suspension includes a plurality of flexures disposed between the movable plate and the stationary portion; and
the conductive bridge includes:
one or more flexible structures connected between the movable plate and the stationary portion, and
one or more metal lines disposed over the one or more flexible structures, and
wherein the flexible structures have a smaller bending stiffness than the plurality of flexures.

5. The system of claim 1, wherein the current path is a coil.

6. The system of claim 1, wherein:
a second cavity is formed between the movable plate and the second cap; and
the second cap includes one or more stops extending into the cavity so that out of plane movement of the movable plate is resisted.

7. The system of claim 1, wherein the magnet is a first magnet; and
further comprising:
a second magnet associated with the second plate plate, and
wherein the second plate and the second magnet are connected with the second cap so that the movable plate is disposed between the first magnet and the second magnet.

8. The system of claim 1, wherein:
the magnet includes a first portion having a north magnet orientation, a second portion having a south magnet orientation, and a transition zone between the first portion and the second portion;
the transition zone includes a plurality of gradations in magnet orientation, wherein some of the gradations are between the north magnet orientation and the south magnet orientation.

9. The system of claim 1, wherein:
the current path is connected with a surface of the movable plate; and
a portion of the surface on which the current path is not connected is micro-machined

10. The system of claim 1, further comprising:
a post extending from the first cap at least partially through the plane;
wherein a cavity is disposed within the movable plate for receiving the post so that a gap exists between the cavity and the post.

11. The system of claim 1, further comprising:
an x capacitive sensor including a first x electrode disposed on the movable plate and a second x electrode disposed on one of the first cap and the second cap and aligned with the first x electrode; and
a y capacitive sensor including a first y electrode disposed on the movable plate and a second y electrode disposed on one of the first cap and the second cap and aligned with the first y electrode;
wherein the x capacitive sensor and the y capacitive sensor are used to determine displacement of the movable plate relative to the one of the first cap and the second cap.

12. The system of claim 1, further comprising:
an x capacitive sensor including a first x electrode disposed on the movable plate, a second x electrode disposed on one of the first cap and the second cap, and a third x electrode disposed on one of the first cap and the second cap;
wherein the second x electrode and third x electrode are aligned with the first x electrode; and
a y capacitive sensor including a first y electrode disposed on the movable plate, a second y electrode disposed on one of the first cap and the second cap, and a third y electrode disposed on one of the first cap and the second cap;
wherein the second y electrode and third y electrode are aligned with the first y electrode; and
wherein the x capacitive sensor and the y capacitive sensor are used to determine displacement of the movable plate relative to the one of the first cap and the second cap.

13. A system for selectively positioning a movable plate, the system comprising:
a movable plate arranged in a plane;
a stationary portion arranged in the plane such that the movable plate is nested within the stationary portion, the stationary portion;
a suspension connected between the movable plate and the stationary portion;
a cap fixedly connected with the stationary portion;
a current path fixedly connected with the movable plate and disposed at least partially within the cavity;
a magnetic field device associated with the current path;
an x capacitive sensor including a first x electrode disposed on the movable plate and a second x electrode disposed on the cap and aligned with the first x electrode; and
a y capacitive sensor including a first y electrode disposed on the movable plate and a second y electrode disposed on the cap and aligned with the first y electrode;
wherein the movable plate can be moved within the plane relative to the stationary portion when a current is applied to the current path; and
wherein the x capacitive sensor and the y capacitive sensor are used to determine displacement of the movable plate relative to the cap.

14. The system of claim 13, further comprising:
a conductive bridge disposed between the stationary portion and the movable plate, the conductive bridge allowing electrical communication between the stationary portion and the movable plate.

15. The system of claim 14, wherein:
the suspension includes a plurality of flexures disposed between the movable plate and the stationary portion; and
the conductive bridge includes one or more metal lines disposed over the plurality of flexures.

16. The system of claim 14, wherein:
the suspension includes a plurality of flexures disposed between the movable plate and the stationary portion; and
the conductive bridge includes:
one or more flexible structures connected between the movable plate and the stationary portion, and
one or more metal lines disposed over the one or more flexible structures, and
wherein the flexible structures have a smaller bending stiffness than the plurality of flexures.

17. The system of claim 1, wherein:
the magnet includes a first portion having a north magnet orientation, a second portion having a south magnet orientation, and a transition zone between the first portion and the second portion;
the transition zone includes a plurality of gradations in magnet orientation, wherein some of the gradations are between the north magnet orientation and the south magnet orientation.

18. The system of claim 13, wherein:
the current path is connected with a surface of the movable plate; and
a portion of the surface on which the current path is not connected is micro-machined

19. The system of claim 1, further comprising:
a post extending from the cap at least partially through the plane;
wherein a cavity is disposed within the movable plate for receiving the post so that a gap exists between the cavity and the post.

20. A method of reducing mass of a movable plate having current paths for positioning a media device, the method comprising:
depositing metal on a surface of the movable plate to form current paths over a first portion of the surface; and
etching a second portion of the surface of the movable plate, so that the first portion disposed beneath the current paths has a thickness with a desired bending characteristic and the second portion has a thickness smaller than the first portion.

21. A method of minimizing a mass of a movable plate having current paths for positioning a media device, the method comprising:
using the movable plate formed of silicon;
forming a layer of thermal oxide on a surface of the movable plate;
depositing a metal layer on the thermal oxide;
etching the metal layer such that a current path is formed; and
etching the thermal oxide such that a bending characteristic of the thermal oxide resists a bending characteristic of the current path.

22. The method of claim 21, wherein the thermal oxide is etched to conform to a shape of the current path.

23. The method of claim 21, wherein the thermal oxide is etched to have a surface area that generally resists the bending characteristic of the current path with equal magnitude.
